(19) United States
(12) Patent Application Publication
(10) Pub. No.: US 2013/0189831 A1
(43) Pub. Date: Jul. 25, 2013

(54) SILICON/GERMANIUM NANOPARTICLE INKS AND METHODS OF FORMING INKS WITH DESIRED PRINTING PROPERTIES

(71) Applicants: Weidong Li, San Jose, CA (US); Gina Elizabeth Pengra-Leung, San Jose, CA (US); Uma Srinivasan, Mountain View, CA (US); Shivkumar Chiruvolu, San Jose, CA (US); Masaya Soeda, Sunnyvale, CA (US); Guojon Liu, San Jose, CA (US)

(72) Inventors: Weidong Li, San Jose, CA (US); Gina Elizabeth Pengra-Leung, San Jose, CA (US); Uma Srinivasan, Mountain View, CA (US); Shivkumar Chiruvolu, San Jose, CA (US); Masaya Soeda, Sunnyvale, CA (US); Guojon Liu, San Jose, CA (US)

(21) Appl. No.: 13/353,645

(22) Filed: Jan. 19, 2012

(51) Int. Cl. H01L 21/20; H01B 1/04; H01B 1/02; B82Y 40/00; B82Y 30/00

(52) U.S. Cl. 438/479; 252/500; 252/512; 977/773; 977/890; 257/E21.09

(57) ABSTRACT

Improved silicon/germanium nanoparticle inks are described that have silicon/germanium nanoparticles well distributed within a stable dispersion. In particular the inks are formulated with a centrifugation step to remove contaminants as well as less well dispersed portions of the dispersion. A sonication step can be used after the centrifugation, which is observed to result in a synergistic improvement to the quality of some of the inks. The silicon/germanium ink properties can be engineered for particular deposition applications, such as spin coating or screen printing. Appropriate processing methods are described to provide flexibility for ink designs without surface modifying the silicon/germanium nanoparticles. The silicon/germanium nanoparticles are well suited for forming semiconductor components, such as components for thin film transistors or solar cell contacts.

### FIELD OF THE INVENTION

The invention pertains to silicon nanoparticle dispersions that can be deposited as suitable inks, such as spin coating inks or screen printing pastes. In particular, the invention can pertain to doped silicon nanoparticle inks.

### BACKGROUND OF THE INVENTION

Silicon is an important commercial material. Many applications of silicon are based on the semiconducting properties of silicon. The semiconducting properties and electron mobilities of silicon can be altered using dopants. The formation of semiconductor devices generally involves the formation of regions of the device with selectively doped silicon in which the dopants alter the electrical conduction properties or other desired properties. Through the selected doping process different domains of the device can be formed that provide functionalities for particular device to exploit the semiconductor properties, such as a diode junction formed with separate materials with a p-type dopant and an n-type dopant. For example, n-type dopants provide excess electrons that can populate the conduction bands, and the resulting materials are referred to as n-type semiconductors. P-type dopants provide electron deficiencies or holes and are used to form p-type semiconductors. Through appropriate doping, a wide range of devices can be formed, such as transistors, diodes and the like.

The wide ranges of semiconductor applications generate commercial relevance for silicon materials in many forms. For example, the formation of large area thin film transistors or the like generates a demand for alternative semiconductor processing approaches. Also, with increasing energy costs and increasing demand for energy, the market for solar cells has been correspondingly increasing. A majority of commercial solar cells comprise photoconducting silicon semiconductors, and differential doping of the semiconductor facilitates harvesting of the photocurrent. Some solar cells have patterning of silicon doping for the formation of doped contacts along the horizontal plane of the device. Thin film silicon solar cells can have dopant variation in a vertical orientation relative to the plane of the device. With increasing performance demands, there are pressures to keep costs down so that improvements in material processing is very desirable as an approach to address performance issues while keeping costs at acceptable levels. Germanium is a semiconducting material that can be an alternative to silicon with similar semiconducting properties. Also, silicon and germanium can form semiconducting alloys with each other.

### SUMMARY OF THE INVENTION

In a first aspect, the invention pertains to a paste comprising a solvent and elemental silicon/germanium nanoparticles having an average primary particle diameter of no more than about 75 nm and a concentration of nanoparticles from about 1 weight percent to about 20 weight percent silicon/germanium nanoparticles. In some embodiments, the paste has a viscosity at a shear rate of about 2 s⁻¹ from about 2 Pa·s to about 450 Pa·s, a viscosity at a shear rate of about 1000 s-1 of no more than about 1 Pa·s, and a ratio of the viscosity at a shear rate of 2 s⁻¹ to the viscosity at a shear rate of 1000 s⁻¹ of at least about 20.

In further aspects, the invention pertains to a silicon nanoparticle paste comprising a solvent and elemental silicon/germanium nanoparticles having an average primary particle diameter of no more than about 75 nm and a concentration of nanoparticles from about 1 weight percent to about 20 weight percent silicon/germanium nanoparticles. In some embodiments, the paste can have a viscosity at a shear rate of about 2 s⁻¹ from about 1 Pa·s to about 450 Pa·s, and the paste can have an average post-printing viscosity at a shear of 2 s⁻¹ that is no less than about 70 percent of an average post-printing viscosity. A simulated print cycle is simulated with the application of a shear rate of about 1000 s-1 to the paste for about 60 seconds followed by applying a low shear rate of about 2 s-1 to the paste for 200 seconds, in which simulated printing comprises subjecting the paste to 20 simulated print cycles and then performing the specified viscosity measurements. The pre-printing and post-printing viscosities are measured at about 25° C.

In additional aspects, the invention pertains to a silicon/germanium ink comprising a solvent and from about 0.25 to about 10 weight percent elemental silicon/germanium nanoparticles having an average primary particle size of no more than about 75 nanometers with a viscosity from about 5 cP to about 75 cP, in which the solvent comprises at least about 95 weight percent alcohol.

In other aspects, the invention pertains to an ink comprising a solvent, from about 0.25 to about 20 weight percent elemental silicon/germanium nanoparticles having an average primary particle size of no more than about 100 nanometers and at least about 1 weight percent silica etching composition.

In further aspects, the invention pertains to a silicon/germanium ink comprising a solvent, from about 0.25 to about 20 weight percent elemental silicon/germanium nanoparticles having an average primary particle size of no more than about 100 nanometers and at least about 1 weight percent silica etching composition.

Additionally, the invention pertains to a method for applying a silicon ink deposit to a silicon substrate having a silica (silicon oxide) overcoat, the method comprising depositing an ink comprising silicon nanoparticles and a silica etchant to form ink deposits over at least a portion of the silica overcoat to etch through the silica overcoat, and drying the ink deposits to remove solvent and silica etchant and to form a silicon nanoparticle deposit in contact with the silicon substrate.

Moreover, the invention pertains to an ink comprising a solvent, from about 0.25 to about 20 weight percent elemental silicon/germanium nanoparticles having an average primary particle size of no more than about 100 nanometers and from about 0.25 to about 15 weight percent silica/germania nanoparticles having an average primary particle size of no more than about 100 nanometers.

Furthermore, the invention pertains to a method for the method for producing silicon/germanium nanoparticle inks, in which the method comprises centrifuging an initial well mixed dispersion comprising silicon/germanium nanoparticles in a solvent, to separate a supernatant silicon nanoparticle dispersion from residue; and further centrifuging the supernatant solution comprising the silicon/germanium nanoparticle dispersion to separate a multiply centrifuged supernatant as a stable silicon/germanium nanoparticle ink.

### BRIEF DESCRIPTION OF THE DRAWINGS

FIG. 1 is a schematic top perspective view of a printed substrate. FIG. 2a is a bottom perspective view of a back contact photovoltaic cell. FIG. 2b is a bottom view of the back contact photovoltaic cell depicted in FIG. 2a showing only the semiconducting layer with doped islands deposited thereon.

FIG. 3 is an optical microscopy image of a film formed from a spin coating ink prepared from 7 nm, intrinsic, silicon nanoparticles. The hash marks in the lower right corner of the image correspond to a length scale of 20 μm.

FIG. 4 is an optical microscopy image of a film formed from a spin coating ink prepared from 7 nm, n++, doped silicon nanoparticles. The hash marks in the lower right corner of the image correspond to a length scale of 20 μm.

FIG. 5 is a composite of optical microscopy images of a film formed from a spin coating ink prepared from 7 nm, p++, doped silicon nanoparticles. The larger image is an enlargement of a portion of the smaller image in the upper left corner and the hash marks in the lower right corner of each image correspond to a length scale of 10 μm.

FIG. 6 is an optical microscopy image of a film formed from a spin coating ink prepared from 30 nm, intrinsic, silicon nanoparticles. The hash marks in the lower right corner of the image correspond to a length scale of 20 μm.

FIG. 7 is an optical microscopy image of a film formed from a spin coating ink prepared from 20 nm, n++, doped silicon nanoparticles. The hash marks in the lower right corner of the image correspond to a length scale of 20 μm.

FIG. 8 is a composite of optical microscopy images of a film formed from a spin coating ink prepared from 25 nm, n+, doped silicon nanoparticles. The larger image is an enlargement of a portion of the smaller image in the upper left corner and the hash marks in the lower right corner of each image correspond to a length scale of 20 μm.

FIG. 9a is an SEM image of a tilted top-view of the film depicted in FIG. 4 showing the top surface morphology.

FIG. 9b is an SEM image of a cross-section of the film depicted in FIG. 9a, taken at higher magnification, showing a portion of the edge and the top surface.

FIG. 10a is an SEM image of a tilted top-view of the film depicted in FIG. 7 showing a portion of an edge and the top surface.

FIG. 10b is an SEM image of a cross-section of the film depicted in FIG. 10a, taken at higher magnification, showing a portion of the edge and top surface.

FIG. 11 is an optical microscopy image of a film formed from a spin coating ink prepared from 7 nm, n++, doped silicon nanoparticles and initially mixed by probe sonication. The hash marks in the lower right corner of the image correspond to a length scale of 20 μm.

FIG. 12 is an optical microscopy image of a film formed from a spin coating ink prepared from 7 nm, intrinsic, silicon nanoparticles and subjected to post-centrifugation sonication at ambient temperature. The hash marks in the lower right corner of the image correspond to a length scale of 50 μm.

FIG. 13 is an optical microscopy image of a film formed form a spin coating ink prepared from 7 nm, n++, doped silicon nanoparticles and subjected to post-centrifugation sonication for 6 hr. at 4° C.-10° C. The hash marks in the lower right corner of the image correspond to a length scale of 50 μm.

FIG. 14 is an optical microscopy image of a film formed from a spin coating ink formed from 7 nm, n++, doped silicon nanoparticles and initially mixed by bath sonication. The ink was subjected to a 1-step centrifugation and was not subjected to post-centrifugation sonication. The hash marks in the lower right corner of the image correspond to a length scale of 50 μm.

FIG. 15 is an optical microscopy image of a film formed from a spin coating ink prepared from 7 mm, n++, doped silicon nanoparticles and initially mixed by bath sonication. The ink was subjected to a 1-step centrifugation and post-centrifugation sonication for 1 hr. at ambient temperature. The hash marks in the lower right corner of the image correspond to a length scale of 50 μm.

FIG. 16 is an optical microscopy image of a film formed from a spin coating ink prepared from 7 nm, n++, doped silicon nanoparticles and initially mixed by bath sonication. The ink was subjected to a 2-step centrifugation and post-centrifugation sonication for 3 hr. at ambient temperature. The hash marks in the lower right corner of the image correspond to a length scale of 50 μm.

FIG. 17 is a graph containing plots of intensity verses secondary particle size of different diluted spin coating inks.

FIG. 18a is an optical microscopy image showing 200 um dots printed with a paste comprising 20 nm, n++, doped silicon nanoparticles and taken after the 5th print cycle. The hash marks in the lower right corner of the image correspond to a length scale of 50 μm.

FIG. 18b is an optical microscopy image showing the screen used to print the dots depicted in FIG. 18a and that was taken after 2 hours of continuous printing. The hash marks in the lower right corner of the image correspond to a length scale of 50 μm.

FIG. 19a is an optical microscopy image of a line, manually screen printed after the 10^{th} print cycle with the screen printing paste used to print the dot depicted in FIG. 18a. The screen printing pasted was not subject to centrifugal planetary mixing after post-centrifugation sonication. The hash marks in the lower right corner of the image correspond to a length scale of 50 μm.

FIG. 19b is an optical microscopy image of a line, manually screen printed after the 10^{th} print cycle with a screen printing paste prepared from 20 nm, n++, doped silicon nanoparticles that was subjected to centrifugal planetary mixing after post-centrifugation sonication. The hash marks in the lower right corner of the image correspond to a length scale of 50 μm.

FIG. 20a is an optical microscopy image of a screen used to manually screen print a dot, taken after 1 hour of continuous printing. The dot was printed with the ink used to print the line depicted in FIG. 19a. The hash marks in the lower right corner of the image correspond to a length scale of 50 μm.

FIG. 20b is an optical microscopy image of a screen used to manually screen print a dot, taken after 1 hour of continuous printing. The dot was printed with the ink used to print the line depicted in FIG. 19b. The hash marks in the lower right corner of the image correspond to a length scale of 50 μm.

FIG. 21a is an optical microscopy image of a line with a width of 200 μm, screen printed during the 10^{th} print cycle with a screen printing paste comprising 3-6 wt % silicon nanoparticles and 0.85 wt % ethyl cellulose. The hash marks in the lower right corner of the image correspond to a length scale of 50 μm.

FIG. 21b is an optical microscopy image of a dot with a diameter of 200 μm, screen printed during the 10^{th} print cycle with a screen printing paste comprising 3-6 wt % silicon nanoparticles and 0.85 wt % ethyl cellulose. The hash marks in the lower right corner of the image correspond to a length scale of 50 μm.

FIG. 22a is an optical microscopy image of a line with a width of 100 μm, screen printed during the 10^{th} print cycle with the screen printing paste used to print the line and dot depicted in FIGS. 21a and 21b. The hash marks in the lower right corner of the image correspond to a length scale of 50 μm.

FIG. 22b is an optical microscopy image of a dot with a diameter of 100 μm, screen printed during the 10^{th} print cycle with the screen printing paste used to print the line and dot depicted in FIGS. 21a and 21b. The hash marks in the lower right corner of the image correspond to a length scale of 50 μm.

FIG. 23a is an optical microscopy image of a line with a width of 200 μm, screen printed on a polished wafer during the 10^{th} print cycle with the screen printing paste used to print the line and dot depicted in FIGS. 21a and 21b. The hash marks in the lower right corner of the image correspond to a length scale of 50 μm.

FIG. 23b is an optical microscopy image of a dot with a diameter of 200 μm, screen printed on a polished wafer during the 10^{th} print cycle with the screen printing paste used to print the line and dot depicted in FIGS. 21a and 21b. The hash marks in the lower right corner of the image correspond to a length scale of 50 μm.

FIG. 24 is an optical microscopy image of a screen used to print a 200 μm line with the screen printing paste used to print the dot and line depicted in FIGS. 21a and 21b. The image was taken after 2 hours of continuous printing.

FIG. 25 is an optical microscopy image of a screen used to print a 100 μm dot with the screen printing paste used to print the dot and line depicted in FIGS. 22a and 22b. The image was taken after the 2 hours of continuous printing.

FIG. 26 is a graph containing plots of viscosity versus shear rate for 3 different ink pastes formed from 20 nm, n++, doped silicon nanoparticles with (top 2 plots) and without (bottom plot) EC as a polymer additive.

FIG. 27a is an optical microscopy image displaying top-view of silicon wafer substrate with screen printed line. The line was printed with a screen printing ink comprising 3-6 wt % silicon nanoparticles and 0.85 wt % EC and the hash marks in the lower right corner of the image correspond to a length scale of 50 μm.

FIG. 27b is an optical microscopy image displaying top-view of silicon wafer substrate with screen printed dot. The dot was printed with a screen printing ink comprising 3-6 wt % silicon nanoparticles and 0.85 wt % EC and the hash mark a in the lower right corner of the image correspond to a length scale of 50 μm.

FIG. 27c is an optical microscopy image displaying top-view of silicon wafer substrate with screen printed pattern. The pattern was printed with a screen printing ink comprising 3-6 wt % silicon nanoparticles and 0.85 wt % EC and the hash marks in the lower right corner of the image correspond to a length scale of 50 μm.

FIG. 28a is an optical microscopy image displaying top-view of silicon wafer substrate with screen printed line. The line was printed with a screen printing ink comprising 3-6 wt % silicon nanoparticles and 2.5 wt % EC and the hash marks in the lower right corner of the image correspond to a length scale of 100 μm.

FIG. 28b is an optical microscopy image displaying top-view of silicon wafer substrate with screen printed dot. The dot was printed with a screen printing ink comprising 3-6 wt % silicon nanoparticles and 2.5 wt % EC and the hash marks in the lower right corner of the image correspond to a length scale of 100 μm.

FIG. 28c is an optical microscopy image displaying top-view of silicon wafer substrate with screen printed pattern. The pattern was printed with a screen printing ink comprising 3-6 wt % silicon nanoparticles and 2.5 wt % EC and the hash marks in the lower right corner of the image correspond to a length scale of 100 μm.

FIG. 29a is an optical microscopy image displaying top-view of silicon wafer substrate with screen printed line. The line was printed with a screen printing ink comprising 0.65 wt % EC and the hash marks in the lower right corner of the image correspond to a length scale of 50 μm.

FIG. 29b is an optical microscopy image displaying top-view of silicon wafer substrate with screen printed dot. The dot was printed with a screen printing ink comprising 0.65 wt % EC and the hash marks in the lower right corner of the image correspond to a length scale of 50 μm.

FIG. 29c is an optical microscopy image displaying top-view of silicon wafer substrate with screen printed pattern. The pattern was printed with a screen printing ink comprising 0.65 wt % EC and the hash marks in the lower right corner of the image correspond to a length scale of 50 μm.

FIG. 30a is an optical microscopy image displaying top-view of silicon wafer substrate with screen printed line. The line was printed with a screen printing ink comprising 3.3 wt % EC and the hash marks in the lower right corner of the image correspond to a length scale of 100 μm.

FIG. 30b is an optical microscopy image displaying top-view of silicon wafer substrate with screen printed dot. The dot was printed with a screen printing ink comprising 3.3 wt % EC and the hash marks in the lower right corner of the image correspond to a length scale of 100 μm.

FIG. 30c is an optical microscopy image displaying top-view of silicon wafer substrate with screen printed pattern. The pattern was printed with a screen printing ink comprising 3.3 wt % EC and the hash marks in the lower right corner of the image correspond to a length scale of 100 μm.

FIG. 31 is an optical microscopy image displaying a top-view of a silicon wafer substrate with a line screen printed with the ink sample used to print the line displayed in FIG. 30a. The printed substrate was cured at 400° C.-500° C. for no more than 15 min. in Air.

FIG. 32 is an optical microscopy image displaying a top-view of a silicon wafer substrate with a line screen printed with the ink sample used to print the line displayed in FIG. 30a. The printed substrate was cured at 500° C. for 30 min. under nitrogen.

FIG. 33a is an optical microscopy image displaying a top-view of a silicon wafer substrate with a line screen printed with a screen printing ink comprising silicon nanoparticles and silicon dioxide nanoparticles.

FIG. 33b is an optical microscopy image displaying a top-view of the silicon wafer substrate depicted in FIG. 33a and shows a different portion of the screen printed line.

### DETAILED DESCRIPTION OF THE INVENTION

Silicon nanoparticle inks can be formed with improved stability and improved deposition properties through the improved engineering of the inks. In particular, rheological properties have been found to be an important evaluation tool to evaluate the silicon inks. With respect to improved processing, centrifugation has been found to be very useful for the removal of contaminants, such as metal contaminants, as well as the removal of species that seem to promote aggregation. Processing with multiple centrifugation steps in which the supernatant is further centrifuged has been found to significant improve ink properties. Furthermore, sonication of the inks is effective to disperse the silicon nanoparticles in a stable way, and in some embodiments with very small silicon nanoparticles, sonication following a centrifugation process can be used to obtain a more stable ink that are observed to form deposits with improved surface uniformity. Sonication is found to have a particular efficacy with respect to improving properties of silicon nanoparticle dispersions. The ink preparation approaches can be combined with proper engineering of the inks, which can involve, for example, selection of the solvent or solvent blend, viscosity and other rheology properties. It has also been discovered that rheology measurements on the inks provide significant information that does not seem to be reflected in light scattering measurements on the dispersions. The properties of the inks can be selected based on the particular application. For some applications, it may be desirable to either include a silica etchant in the silicon ink or silica nanoparticles in addition to the silicon nanoparticles. If the ink comprises both elemental silicon nanoparticles and silica nanoparticles, the silicon can be doped, the silica can be doped, or both the silicon and the silica can be doped.

Good dispersions of silicon nanoparticles can be formed without stabilizing the dispersions using non-solvent organic compositions chemically bonded to the particle surfaces. Solvents can interact with the native particle surfaces with varying interactions as described further below. The dispersions with unmodified silicon particles can be formulated at high concentrations of silicon particles and the properties of the dispersions can be appropriately adjusted for a desired coating ink, such as a spin coating ink, an inkjet ink, or a printing paste. In alternative embodiments, the particles are surface modified with an organic composition to selectively alter the dispersion properties of the inks. The inks upon deposition, e.g., coating or printing, can be used for the delivery of dopant elements in a desirable form for driving into a substrate and/or the deposited silicon particles can be sintered into a component of a device.

The processing to form improved silicon nanoparticle inks can be scaled for the formation of commercial quantities of inks. The ability to form high quality silicon nanoparticle inks without chemically bonding a surface modifying agent to the particles simplifies both the processing to form the inks and the processing of deposited inks into a specific product. The ability to print silicon nanoparticles, such as highly doped nanoparticles, using high quality inks can provide significant processing advantages for printed electronics, solar cell component formation and other semiconductor applications. In particular, the silicon nanoparticle inks can be desirably used for forming patterned doped contacts for crystalline solar cells, for patterned electronic components or for the formation of intrinsic and doped layers, such as for formation of electronic components or thin film solar cells.

High quality silicon/germanium nanoparticles are suitable for the formation of relatively high concentration dispersions of the nanoparticles. Highly concentrated dispersions have been formulated without modifying the surface of the particles with organic compositions, while being able to achieve desired ink properties over a broad range, although in some embodiments, surface modification of the particles can be performed with chemical moieties bonded to the surface. However, it is not always desirable to use the highest particle concentrations in stable dispersion since there may be other factors motivating lower particle concentrations.

Silicon/germanium refers herein, including the claims, to elemental silicon, elemental germanium, alloys thereof or mixtures thereof. To simplify the discussion, elemental germanium and alloys of germanium with silicon are generally not explicitly discussed. While the discussion below focuses on silicon, the analogous processing of and compositions with germanium and alloys with silicon follows from the discussion based on the similar chemistries of the elements. Similarly, the use of silica or germania nanoparticles are described in some embodiments, and silica/germania refers herein, including the claims, to silica (silicon oxide), germania (germanium oxide), combinations thereof and mixtures thereof. The discussion of silica herein generally can correspondingly apply to germania based on the similarities of the compositions.

As described herein, elemental silicon inks can be formulated for suitable printing processes for commercial applications. The ability to form good dispersions without chemical modification of the silicon nanoparticle surfaces with an organic compound simplifies processing of the particles after printing. For appropriate embodiments, if there are no organic components bonded to the particles to remove, the silicon nanoparticles can be processed for the formation of semiconductor components with reduced processing both before and after deposition to achieve equivalent low levels of contaminants. Also, the ability to form the dispersions without organic chemical modification of the silicon nanoparticles can reduce the processing steps to form the inks. Furthermore, the processing to form organic modification of the particles involves the use of additional chemicals that can introduce further contaminants to the particle dispersion. Based on improved processing techniques, the particles can be transferred between solvents or formulated with desired solvent blends for production of desired ink formulations, which can be formed with very low levels of contamination. Processing techniques for the inks into corresponding devices can be selected based on the particular application.

Improved inks are described herein based on improved processing approaches. In particular, the particles are initially mixed with a selected solvent or solvent blend. The mixing can involve sonication or mechanical mixing, such as with a mill, blender or the like. The degree of the initial mixing can influence the concentration of particles that are stably integrated into the dispersion. After this initial mixing, the mixture can be subjected to centrifugation. The centrifugation process separates a portion of the less well dispersed particles and possibly contaminants from the dispersion. It is not completely clear what properties result in the settling of the particles during the centrifugation although the surface properties of the particles are believed to influence the settling of the particles. In general, improved ink properties are obtained if the supernatant, which is intended to include a portion thereof, is centrifuged again, and additional centrifugation steps can be used if desired. The supernatant from the last centrifugation step is maintained for the formation of the dispersion. After centrifugation, the supernatant dispersion may or may not be sonicated to further process the dispersion. For silicon nanoparticles with average primary particle sizes of no more than about 15 inn, the process steps of mixing, centrifugation and sonication seem to be particularly useful for the formation of improved dispersions with increased stability, shelf life and significantly improved printing properties. More generally, it is desirable to use at least one sonication processing step, which can be before or after centrifugation.

Solvents generally interact with solutes with various interactions, such as hydrogen bonding, polar interactions as well as various interactions that can have ranges of bonding versus non-bonding characteristics. These various states of interaction are at equilibrium within the solution/dispersion. Inorganic nanoparticles, such as silicon nanoparticles, are a particular type of solute. In general, for more complex solutes and/or dispersed species, such as inorganic nanoparticles, the solute-solvent interactions are generally complex and in many circumstances not completely understood. The degree of interactions with the solvent can cover a range of binding strengths with corresponding degrees of reversibility of the interactions, such as with drying to remove the solvent. With the reference to un-modified silicon particles herein, such an indication does not take into account any potential solvent interactions with the particles.

It has been proposed that ethanol and ethylene glycol form reactive species in solution with silicon particles. This interaction seems to be significantly pH dependent and to also depend on the degree of oxidation of the particle surfaces as well as the presence of dissolved oxygen in the solvent. This phenomenon is described further in Ostraat et al., “The Feasibility of Inert Colloidal Processing of Silicon Nanoparticles,” J. of Colloidal and Interface Science, 283 (2005) 414-421, incorporated herein by reference. In the experience of the current inventors, observations suggest that isopropyl alcohol forms interactive species with the particle surfaces, but that the isopropyl alcohol is effectively completely removed through evaporation suggesting that any solvent-particle interactions are reversible under conditions of solvent removal. As described in the Examples below, the silicon particles presently have a very low level of surface oxidation. Other observations suggest that ethylene glycol and propylene glycol may be more difficult to completely remove with solvent evaporation. However, it is clear that the solvent-particle interactions are generally of a different character from strong bonding interactions of specific surface modification compositions that have been described for modifying the particle surfaces to alter the solvent interactions with the modified particle surfaces. In particular, the specific solvent modifying compositions used to modify the solvent interactions are generally designed to be effectively irreversible under conditions in the ink in order to support dispersion in different types of solvents.

It should be noted that in some embodiments herein, the silicon nanoparticles are synthesized under conditions to isolate the particles from oxygen. Thus, the silicon nanoparticles can be synthesized with little or no surface oxidation. While these particles nevertheless can be dispersed very well in alcohol containing solvents, it is not clear if the interactions with the alcohols would be similar to the interactions with silicon particles that have been exposed to air. Due to the presence of hydrogen during the particle synthesis, it is possible that the surface includes Si—H bonds. There is no evidence on whether or not these particles can chemically bond to any alcohol solvent.

Improved inks are described herein based on results from coating and printing experiments. The processing to achieve the better results has been determined generally, but the characterization of the inks is relatively complex with respect to the particular improved properties. In particular, the improved silicon inks have notably improved printing properties, but the measurements of secondary particle sizes in the dispersions are found to be not distinguishing with respect to ink quality beyond certain levels of improvement. Based on these observations, it seems that the interactions within the dispersion are subtle, and dynamic measurements of the inks, such as rheological measurements, seems to interrogate properties of the inks that are difficult to measure in static measurements, such as light scattering. An objective measure of silicon nanoparticle ink quality has been found to be the stability of the ink viscosity over time. In particular, the silicon nanoparticle inks that have stable viscosities over time are found to have significantly improved coating and printing properties. As noted above, a processing approach to achieve these good results generally comprises a mixing step, followed by a centrifugation step, which is then followed by a sonication step.

Due to its versatility, laser pyrolysis is an excellent approach for efficiently producing a wide range of nanoscale particles with a selected composition and a narrow distribution of average particle diameters. In particular, laser pyrolysis is a desirable technique for the production of crystalline silicon nanoparticles, although in principle inks described herein can be formulated with silicon submicron particles from other sources that can correspondingly produce high quality and uniform particles. In some embodiments of particular interest, the particles are synthesized by laser pyrolysis in which light from an intense light source drives the reaction to form the particles from an appropriate precursor flow. Lasers are a convenient light source for laser pyrolysis, although in principle other intense, non-laser light sources can be used. The particles are synthesized in a flow that initiates at a reactant nozzle and ends at a collection system. Laser pyrolysis is useful in the formation of particles that are highly uniform in composition and size. The ability to introduce a range of precursor compositions facilitates the formation of silicon particles with selected dopants, which can be introduced at high concentrations. Also, laser pyrolysis is a convenient approach for the synthesis of silica, i.e., silicon oxide, such as SiO₂, and germania, such as GeO₂, as described in U.S. Pat. No. 7,892,872 to Hieslmair et al. (hereinafter the '872 patent), entitled “Silicon/Germanium Oxide Particle Inks, Inkjet Printing and Process for Doping Semiconductor Substrates,” incorporated herein by reference.

For the formation of high quality stable inks, it is desirable to use uniform silicon nanoparticles. Laser pyrolysis can effectively produce uniform particles due to rapid quenching of the product particles as the particles leave the reaction zone. The enhanced quenching of particles using an inert gas flow mixed with the product flow downstream from the reaction zone is described in published U.S. patent application 2009/0020411 to Holunga et al., entitled “Laser Pyrolysis With In-Flight Particle Manipulation for Powder Engineering,” incorporated herein by reference. Nozzle designs for a laser pyrolysis reactor that deliver a quenching gas in parallel with the reactant flow is described in copending U.S. patent application Ser. No. 13/070,286 to Chiruvolu et al. (the “286 application”), entitled “Silicon/Germanium Nanoparticle Inks, Laser Pyrolysis Reactors for the Synthesis of Nanoparticles and Associated Methods,” incorporated herein by reference. In some embodiments based on the improved nozzle designs, a distinct entrainment flow of inert gas can be provided around both the reactant flow and the inert quench gas flow. The entrainment flow can facilitate particle nucleation and/or more efficient quenching of the particles. The entrainment flow generally has a higher velocity than the other flows and a relatively large flow volume.

In the laser pyrolysis process, the dopant element(s) are introduced into the reactant stream as a suitable composition such that the elements can be incorporated into the product particles. Laser pyrolysis can be used to form doped silicon particles with a wide range of selected dopants or combinations of dopants, which can be introduced at high concentrations. Specifically, dopant levels of several atomic percent have been achieved. For the doping of semiconductor substrates, desirable dopants include, for example, B, P, Al, Ga, As, Sb and combinations thereof. The general use of laser pyrolysis for the formation of a range of materials including doped silicon nanoparticle is described in published U.S. Pat. No. 7,384,680 to Bi et al., entitled “Nanoparticle Production and Corresponding Structures,” incorporated herein by reference.

The ability to achieve high dopant levels make the corresponding inks particularly desirable for applications where dopants are transferred to a semiconducting material from the silicon nanoparticles, or for the formation directly of components of devices with high dopant levels through the sintering of the silicon nanoparticles. The high dopant levels can be achieved while also having control of average primary particle diameters and while achieving dispersible nanoparticles with good uniformity. Laser pyrolysis was used to synthesize doped silicon nanoparticles used to form improved inks that are described in the Examples below.

Laser pyrolysis apparatuses and processes have been redesigned to achieve exceedingly low metal contaminations for silicon nanoparticles. Specifically, the precursors can be supplied in extremely purified forms, and the apparatus can be designed to reduce introduction of metal contaminants from the reactor. Also, the product particles are collected and handled in a controlled manner to reduce or eliminate metal contaminants resulting from handling the particles. Based on these improved designs, silicon nanoparticles can be synthesized with a very high level of purity with respect to metal elements. Thus, most metal contaminant concentrations for silicon nanoparticle inks can be reduced to levels of no more than about 20 parts per billion by weight (ppb) for inks with a 10 weight percent particle concentration, and total metal contamination can be reduced to levels of no more than about 100 ppb by weight ink. To further remove contaminants in the formation of the dispersions, centrifugation can be used to remove contaminants from the dispersions with the pure silicon nanoparticles remaining disbursed in the liquid.

The surfaces of the silicon particles generally have various degrees of oxidation and/or hydrogenation, which can depend on the synthesis conditions as well as the handling of the particles following synthesis, and such hydrogenation or oxidation is not an organic modification of the particles. It has been found that collection of the elemental silicon nanoparticles isolated from the ambient atmosphere and isolation of the particles during further processing can substantially reduce the oxidation of the particles. Silicon nanoparticles are generally crystalline, and silicon submicron particles produced by laser pyrolysis generally have a high level of crystallinity. In general, the particle surface represents a termination of the particle lattice, and the bonds of the surface silicon atoms bond appropriately to avoid dangling bonds. The surface can terminate with distorted structures to accommodate multiple bonds between silicon atoms or bonds with other atoms, such as bridging oxygen atoms, —OH bonds or —H bonds. For silicon particles formed with silane precursors, there are generally quantities of hydrogen available during the formation of particles that can result in some degree of hydrogenation of the silicon. Contact with air may result in some oxidation of the surface.

In addition to the general reduction of particle contamination, the silicon nanoparticles can be produced with a low level of oxidation. Similar techniques to reducing contaminants can facilitate formation and collection of particles with low oxidation levels. In particular, the reactants can be introduced such that the reactant flow has very low levels of oxygen, and the particles can be collected in isolation from the ambient atmosphere. The collected particles can be transferred in a sealed container to a closed environment for further processing into an ink without any significant exposure to the ambient atmosphere. Of course, a subsequent measurement of the oxygen content would desirably involve measurement of the particles without exposing the particles significantly to the atmosphere, as described in the examples below.

The properties of dispersions of nanoparticles, among other factors, depend significantly on the interactions of the particle surface and the liquid solvent that is functioning as the dispersant. To help control this interaction, molecules can be chemically bonded to the surface of the silicon particles. In general, the molecules bonded to the surface of the silicon particles are organic, although the compounds can comprise silicon based moieties and/or other functional groups in addition to organic moieties. The character of the bonded molecules can then be selected to facilitate the formation of a good dispersion in a selected solvent or blend of solvents. Some of the desired ink formulations can take advantage of surface modification of the silicon particles, and surface modification is described further below. Surface modification of silicon particles is also described further in published U.S. patent application 2008/0160265 to Hieslmair et al., entitled “Silicon/Germanium Particle Inks, Doped Particles, Printing and Processes for Semiconductor Applications,” incorporated herein by reference.

In some embodiments, it can be desirable for the silicon particles used in the dispersion to be free from chemical modification with an organic composition. While, in principle, the organic moieties can be removed during processing after printing or other deposition of the silicon ink prior to use of the deposited silicon particles for device formation, the presence of the organic moieties in the inks can lead to carbon contamination of the silicon materials after processing of the silicon into a component. The electrical properties of the material can be strongly dependent on the presence of impurities including carbon. Therefore, the ability to process the inks with silicon particles without chemically bonded organic moieties can simplify processing and reduce average contaminant levels, or in certain cases may also provide a more flexible device fabrication process flow. Furthermore, processing steps related to the chemical modification with an organic moiety as well as steps related to removal of the chemical modifications clearly can be eliminated if the particles are not chemically modified with organic moieties.

The dispersions can be formed at high concentrations, and the properties of the dispersions can be engineered over desirable ranges based on particular applications. In particular, the solvent properties for forming the initial dispersion can be significant to be able to form the dispersions of the particles without surface modification. The characteristics of the dispersion can be evaluated through an examination of secondary particle properties, such as Z-average particle size and particle size distribution, measured in the dispersion using generally light scattering, which are measures of the size of the dispersed particles in the liquid. In particular, good dispersions can be characterized with respect to the secondary particle sizes and distributions. Dispersions that are too concentrated for direct measurement of secondary particle sizes can be diluted, for example, to a 1 weight percent concentration for the secondary particle characterization. In particular, it can be desirable for the Z-average particle size to be no more than about 250 nm and in further embodiments no more than about 150 nm. In general, it has been found that rheology properties can provide further information on the ink properties that do not seem to be reflected in the secondary particle size measurements, and this understanding provides an important tool in ink design and characterization.

Once an initial good dispersion is formed with the silicon nanoparticles in an appropriate solvent to form the good dispersion, the solvent or blends thereof can be manipulated to form an overall ink with selected properties while maintaining the good dispersion of the particles. Specifically, techniques have been developed for more versatile exchange of solvents or formation of solvent blends such that a desirable solvent system can be selected for a particular printing approach. With the ability to provide highly uniform silicon nanoparticles in high concentration dispersions with selected solvents, inks can be formulated that can be printed using desirable approaches. After printing, the inks can be used to form components of semiconductor devices or as a dopant source to be driven into an underlying semiconductor material. In particular, the silicon inks can be used for forming components of solar cells or of electronic devices, such as thin film transistors. In some embodiments, the particles can be incorporated directly into a component of an ultimate product.

The engineering of a desired silicon ink can involve several parameters. A starting point for ink formulations can involve the formation of well dispersed silicon particles. Once the particles are well dispersed, the resulting dispersion can be appropriately modified to form a selected ink. Solvent can be removed by evaporation to increase the particle concentration, and/or solvent or solvents can be added to form a solvent blend or a lower concentration of the particles in the dispersion. A good dispersion is characterized by the nanoparticles remaining suspended, with no significant particle settling, for at least an hour without application of additional mixing. At higher particle concentrations of the inks, the secondary particle sizes cannot be directly measured by optical methods. But the higher concentration inks can be evaluated by the lack of particle settling, i.e., remaining a good dispersion, and by diluting the concentrated ink to a concentration where the secondary particle size can be measured.

It has been found that appropriate characterization of dispersions generally involves several properties to provide sufficient information to evaluate the significant functional characteristics of the inks. In particular, measurements of DLS dispersed secondary particle sizes does not seem to correlate with the printing properties once the quality of the ink has achieved a good level. However, rheology measurements can provide further information relating to the handling of the inks in a deposition context, and appropriate rheology measurements can be effectively used to provide further significant characteristics of the inks along with primary particles size measurements, secondary particle size measurements, and compositions of the inks. As is conventional in the art, references to viscosity without explicit indication of a shear rate imply that the viscosity measurements are at a low shear limit, which can be effectively expressed as a shear of 2 s⁻¹. Also unless indicated otherwise, viscosity measurements are made at 25° C., e.g., room temperature.

The design of a silicon ink can balance several objectives. The selected deposition technique can provide boundaries on the parameters of the ink properties. Also, the quality of the resulting silicon nanoparticle deposit, such as the uniformity, smoothness and the like, can also be dependent on the subtle aspects of the ink characteristics. The rheology of the ink can be tested to help to estimate the quality of the ink with respect to resulting deposition.

For many silicon ink formulations, the inks have a relatively large particle concentration, for example, at least about 0.5 weight percent or possibly significantly higher. With improved processing techniques and ink formulations described herein, the inks can be formulated with high silicon particle concentrations and with desirable rheological, i.e., fluid, properties. Suitable inks are described for coating deposition or printing, which generally involves a patterning during deposition. Suitable printing inks can be formulated for inkjet printing, gravure printing and screen printing. Suitable coating techniques include, for example, spin coatings, spray coating, knife edge coating and the like. Other inks can be similarly formulated based on this teaching. To obtain desired thickness of deposited inks, a coating or printing process can be repeated to form multiple layers of the ink with a corresponding greater thickness.

Furthermore, for some applications it may be desirable to use somewhat lower ink concentrations as a way to control thicknesses of deposits. Specifically, the obtain a thinner coating of deposited silicon particles, the ink can be made more dilute such that a lower coverage of silicon particles remains following deposition of a certain amount of ink and drying of the ink. So moderate ink concentrations can be effective for the deposition of sufficient quantities of silicon nanoparticles while maintaining desired rheology and not depositing more material than desired. For example, with screen printing pastes, there are constraints on the printing process in terms of the viscosity of the pastes as well as the practical coating thicknesses. Thus, if a thinner silicon particle deposit is desired, the screen print paste can be made more dilute so that after the other paste components are removed, the remaining silicon nanoparticle deposit can be thinner based on a smaller quantity of the nanoparticles deposited. To achieve the desired paste viscosity for screen printing, the solvent composition can be changed to compensate for viscosity changes resulting from the lowering of the silicon nanoparticle concentration in the inks.

In some embodiments, it has been found that alcohol solvents can be used effectively for formulating desirable inks. In particular, coating inks can be formed with individual solvents, such as appropriate alcohols. For example, it has been found that high quality spin coating inks can be formulated with a single solvent component. However, for many embodiments of printing inks with silicon nanoparticles, a desired ink can advantageously comprises a blend of solvents with desired properties to achieve target ink properties. In general, if a blend of solvents is used, the solvents form a single liquid phase either due to miscibility or solubility of the solvents relative to each other.

For appropriate embodiments, convenient processing approaches can be adapted for the formation of inks with a blend of organic liquids, i.e., solvents. Blends of organic solvents are particularly useful for the formation of printing pastes. Specifically, the blend of solvents generally can comprise a first low boiling temperature solvent, generally having a boiling point of no more than about 165° C. and a second high boiling temperature solvent, generally having a boiling point of at least about 170° C. The solvents are generally selected to form a single liquid phase upon mixing. The lower boiling solvent can be removed upon printing of the ink to stabilize the printed material, and the higher boiling solvent can be removed upon further processing of the printed material.

While spin coating inks can be formed with desirable properties using a single alcohol solvent, other coating inks can be effectively formulated with a blend of solvents. With respect to screen printing pastes for semiconductor applications, the pastes are generally significantly non-Newtonian. In particular, the pastes are stable on the screen with a high viscosity at a low shear limit. During the printing process, the ink is subjected to a high shear that results in a large drop in viscosity as the ink, i.e., paste, is deposited through openings in the screen. The paste has a moderate but effectively controlled spreading on the substrate. After printing, the paste resumes a low shear environment and the printed paste stabilizes on the substrate. Solvent evaporation of the printed paste can further stabilize the paste after printing prior to further processing of the printed substrate.

Soluble polymers have been known to improve silicon paste properties. For example, the use of polyvinyl alcohol and ethyl cellulose as binders for screen printing silicon particle pastes is described in U.S. Pat. No. 4,947,219 to Boehn, entitled “Particulate Semiconductor Devices and Methods,” incorporated herein by reference. Also, the use of high molecular weight molecules, such as ethyl cellulose, have been described for use in silicon nanoparticle inks in published U.S. patent application 2011/0012066 to Kim et al., entitled “Group IV Nanoparticle Fluid,” incorporated herein by reference. As described herein, cellulose ethers, such as ethyl cellulose, have been found to significantly improve screen printing properties for high quality silicon nanoparticle pastes. In particular, the presence of the cellulose significantly improves the rheology properties of the silicon nanoparticle pastes with appropriately engineered solvent system. The pastes by design are very non-Newtonian.

A centrifugation process step removes a fraction of the dispersed material. The amount of solids that separate in the centrifugation process depends on the centrifugation conditions as well as the processing used to form the dispersion prior to centrifugation. As described herein, improved inks can be obtained using multiple centrifugation steps. In particular, the supernatant from a first centrifugation step can be centrifuged again to produce a supernatant that can be used to form an improved silicon ink, including pastes. Centrifugation has been found to significantly remove contaminants, especially metal contaminants, from the dispersion. In addition, centrifugation removes particle components from the dispersion that evidently lower the quality of inks, although the properties of these removed particle components do not seem to be reflected in light scattering measurements. As described below, in the ultimate inks, differences in the theological properties of the inks are identifiable, but it is not clear form a physical perspective what particle interactions give rise to the observed behaviors.

For small nanoparticles with an average primary particle size of no more than about 15 nm, improved processing can comprise an initial mixing step to form a good silicon nanoparticle dispersion, centrifugation to remove less well dispersed components, which can include contaminants, and a sonication step after the centrifugation. Between the formation of the initial dispersion and the centrifugation, the solvent composition and/or the concentration can be adjusted as desired. The initial mixing can be performed with a selected mixing approach, such as sonication or mechanical mixing. The initial mixing significantly influences the concentration of the resulting ink. However, as long as reasonable initial mixing is performed to form a stable dispersion, the characteristics of the initial mixing seem to not significantly change the properties of the final ink. For the small silicon nanoparticles, the combination of sonication following centrifugation provides a synergistic effect that is not presently understood. While not wanting to be limited by theory, the evidence suggests that centrifugation removes moieties that are not subject to further processing by sonication to form the desired high quality inks.

It has been observed generally that good dispersions formed with equivalent silicon nanoparticles generally have comparable dynamic light scattering measurements that are designed to measure secondary particle sizes, although evidence suggests that the dispersions are not equivalent with respect to deposition properties. Dynamic light scattering is believed to measure secondary particle size in solution with some influence of a solvation layer of solvent interacting with particles. Secondary particle size would seem to relate to degree of particle agglomeration within the dispersion. Evidence strongly suggests that there are significant interactions within the dispersion that are not reflected in the light scattering measurements.

The improved processing approaches described herein provide for silicon nanoparticle inks with improved printing properties. Thus, improved coating and printed structures can be formed from the inks. In particular, coatings with increased smoothness and uniformity can be formed. Similarly, inks with improved printing properties with respect to patterning and uniformity can be performed. The resulting structures can then have corresponding improved structural features. These improvements can result in product devices with improved performance.

The improved inks are well suited for deposition for a range of applications, such as formation of solar cell components, electronic circuit components or the like. The ability to deliver highly doped elemental silicon with a low contamination level provides the ability to form components with good electrical properties with moderate resolution. In particular, doped inks can be used to form doped contacts for crystalline silicon solar cells. Similarly, the inks can be used to form components of thin film transistors. Upon deposition and drying of the inks, the resulting nanoparticle deposits can be processed into densified silicon structures.

For certain applications, it may be desirable to reduce the likelihood that the silicon particles get oxidized during processing or that the substrate on which the silicon ink is printed has silicon oxide removed. This can be accomplished by incorporating a silica etchant into the silicon nanoparticle ink. An appropriate concentration of the silica etchant can be included such that the fluid properties of the ink are desirable. Thus, if the silicon ink with etchant is used on a silicon surface, any silica on the surface can be etched by the silicon ink so that the silicon ink is contacting a cleaned silicon substrate surface. This approach may eliminate a separate etching step to prepare a silicon surface for printing with the silicon ink.

However, in other embodiments it may be desirable to include silica along with the silicon nanoparticle inks. Doped silica nanoparticles can be synthesized by laser pyrolysis, and these particles can be dispersed well into solvents that are compatible with the silicon nanoparticle inks. The presence of silica nanoparticles may facilitate dopant drive in for some embodiments, and the silica may facilitate removal of ink remnant if desired after additional processing, such as dopant drive in.

In general, the inks are suitable for forming semiconductors for a variety of applications. In particular, the inks are suitable for the formation of various solar cell structures based on elemental silicon as at least a component. In particular, solar cells can be based on elemental silicon as the primary light absorbing photoconductor. The light absorbing photoconductor can be primarily highly crystalline silicon. In alternative embodiments, amorphous and/or nanocrystalline silicon can be the primary light absorbing material, which can have a very small thickness due to the greater absorption of light. The silicon inks can be used to form one or more components of the solar cell. For example, the silicon inks can be used to form highly doped silicon contacts for back contact solar cells or selective emitters.

### Particle Properties

The desirable silicon nanoparticle dispersions described herein are based in part on the ability to form high quality silicon nanoparticles with or without dopants. As described above, laser pyrolysis is a particularly suitable approach for the synthesis of highly uniform silicon submicron particles or nanoparticles. Also, laser pyrolysis is a versatile approach for the introduction of desired dopants at a selected concentration, such as high dopant concentrations. Also, the surface properties of the silicon particles can be influenced by the laser pyrolysis process, although the surface properties can be further manipulated after synthesis to form desired dispersions. Small and uniform silicon particles can provide processing advantages with respect to forming dispersions/inks.

In some embodiments, the particles have an average diameter of no more than about one micron, and in further embodiments it is desirable to have particles with smaller particle sizes to introduce desired properties. For example, nanoparticles with a small enough average particle size are observed to melt at lower temperatures than bulk material, which can be advantageous in some contexts. Also, the small particle sizes provide for the formation of inks with desirable properties, which can be particularly advantageous for a range of coating and/or printing processes since small uniform silicon particles can be advantageous for the formation of inks with desirable rheological properties. Generally, the dopants and the dopant concentration are selected based on the desired electrical properties of the subsequently fused material or to provide a desired degree of dopant migration to an adjacent substrate. The dopant concentrations can influence the particle properties also.

In particular, laser pyrolysis is useful in the formation of particles that are highly uniform in composition, crystallinity, and size. A collection of submicron/nanoscale particles may have an average diameter for the primary particles of no more than about 500 nm, in some embodiments from about 2 nm to about 100 nm, alternatively from about 2 nm to about 75 nm, in further embodiments from about 2 nm to about 50 nm, in additional embodiments from about 2 nm to about 40 nm, and in other embodiments from about 2 nm to about 35 nm. A person of ordinary skill in the art will recognize that other ranges within these specific ranges are covered by the disclosure herein. In particular, for some applications, smaller average particle diameters can be particularly desirable. Particle diameters and primary particle diameters are evaluated by transmission electron microscopy. Primary particles are the small visible particulate units visible in the micrograph without reference to the separability of the primary particles. If the particles are not spherical, the diameter can be evaluated as averages of length measurements along the principle axes of the particle.

As used herein, the term “particles” without qualification refers to physical particles, which are unfused, so that any fused primary particles are considered as an aggregate, i.e. a physical particle. For particles formed by laser pyrolysis, if quenching is applied, elemental silicon particles can have a size roughly of the same order of magnitude as the primary particles, i.e., the primary structural element within the material. Thus, the ranges of average primary particle sizes above can also be used with respect to the particle sizes to the extent that fusing is negligible. If there is hard fusing of some primary particles, these hard fused primary particles form correspondingly larger physical particles, and some noteworthy fusing is observed for very small particles with an average primary particle size of less than about 10 nm. The primary particles can have a roughly spherical gross appearance, or they can have non-spherical shapes. Upon closer examination, crystalline particles may have facets corresponding to the underlying crystal lattice. Amorphous particles generally have a spherical aspect.

Because of their small size, the particles tend to form loose agglomerates due to van der Waals and other electromagnetic forces between nearby particles. Even though the particles may form loose agglomerates, the nanometer scale of the particles is clearly observable in transmission electron micrographs of the particles. The particles generally have a surface area corresponding to particles on a nanometer scale as observed in the micrographs. Furthermore, the particles can manifest unique properties due to their small size and large surface area per weight of material. These loose agglomerates can be dispersed in a liquid to a significant degree and in some embodiments approximately completely to form dispersed particles.

The particles can have a high degree of uniformity in size. Laser pyrolysis generally results in particles having a very narrow range of particle diameters. As determined from examination of transmission electron micrographs, the primary particles generally have a distribution in sizes such that at least about 95 percent, and in some embodiments 99 percent, of the particles have a diameter greater than about 35 percent of the average diameter and less than about 280 percent of the average diameter. In additional embodiments, the particles generally have a distribution in sizes such that at least about 95 percent, and in some embodiments 99 percent, of the primary particles have a diameter greater than about 40 percent of the average diameter and less than about 250 percent of the average diameter. In further embodiments, the primary particles have a distribution of diameters such that at least about 95 percent, and in some embodiments 99 percent, of the primary particles have a diameter greater than about 60 percent of the average diameter and less than about 200 percent of the average diameter. A person of ordinary skill in the art will recognize that other ranges of uniformity within these specific ranges are contemplated and are within the present disclosure.

Furthermore, in some embodiments essentially no primary particles have an average diameter greater than about 5 times the average diameter, in other embodiments about 4 times the average diameter, in further embodiments 3 times the average diameter, and in additional embodiments 2 times the average diameter. In other words, the primary particle size distribution effectively does not have a tail indicative of a small number of particles with significantly larger sizes. This is a result of the small reaction region to form the inorganic particles and corresponding rapid quench of the inorganic particles. An effective cut off in the tail of the size distribution indicates that there are less than about 1 particle in 10⁶ has a diameter greater than a specified cut off value above the average diameter. High primary particle uniformity can be exploited in a variety of applications.

High quality particles can be produced that are substantially unfused. However, for the production of very small primary particle sizes, e.g., less than 10 nm average diameter, at higher production rates, the primary particles can involve substantial fusing into a nanostructured material. These particles can still be dispersed into a liquid to produce desired ranges of secondary particle size. Even though the particles with very small primary particle diameters may have significant fusing, these particles may still be desirable for applications in which the small primary particle size and corresponding high surface areas can facilitate dopant delivery and/or fusing of the deposited inks into corresponding structures.

The silicon particles can further be characterized by BET surface areas. The surface area measurements are based on gas adsorption onto the particle surfaces. The theory of BET surface area was developed by Brunauer et al., J. Am. Chem. Soc. Vol. 60, 309 (1938). The BET surface area evaluation cannot directly distinguish small particle sizes from highly porous particles, but the surface area measurements nevertheless provide useful characterization of the particles. BET surface area measurements are an established approach in the field, and for silicon particles the BET surface area can be determined with an N₂ gas absorbate. The BET surface area can be measured with commercial instruments, such as a Micromeritics Tristar 3000™ instrument. The silicon particles described herein can have BET surface areas ranging from about 100 m²/g to about 1500 m²/g and in further embodiments, from about 200 m²/g to about 1250 m²/g. A person of ordinary skill in the art will recognize that additional ranges within the explicit ranges above are contemplated and are within the present disclosure. The particle diameters can be estimated from the BET surface areas based on the assumption that the particles are non-porous, non-agglomerated spheres.

X-ray diffraction can be use to evaluate the crystallinity of the particles. Furthermore, crystalline nanoparticles produced by laser pyrolysis can have a high degree of crystallinity. For laser pyrolysis synthesis of crystalline silicon particles, it is generally believed that the primary particles correspond with a crystallite. However, x-ray diffraction can also be used to evaluate the crystallite size. In particular, for submicron particles, the diffraction peaks are broadened due to truncation of the crystal lattice at the particle surface. The degree of broadening of the x-ray diffraction peaks can be used to evaluate an estimate of the average crystallite size. While strain in the particles and instrument effects can also contribute to broadening of the diffraction peaks, if the particles are assumed to be essentially spherical, the Scherrer equation, which is well known in the art, can be used to provide a lower limit on the average particle size. Meaningful broadening is only observed for crystallite sizes less than about 100 nm. If the particle sizes from TEM evaluation of primary particle diameters, particle size estimates from the BET surface areas and the particle sizes from the Scherrer equation are roughly equal, this determination provides significant evidence that the fusing of the particles is not excessive and that the primary particles are effectively single crystals.

In addition, the submicron particles may have a very high purity level. Silicon particles can be produced with very low levels of metal impurities using laser pyrolysis with appropriate particle handling procedures. Low metal impurity levels are very desirable from the perspective of semiconductor processing. As described further below, the particles can be placed into dispersions. In the dispersions, processing such as centrifugation can be performed to reduce impurities. In the resulting dispersions, the contamination by metal elements can be very low based on desired handling of the particles. The contaminant levels can be evaluated by ICP-MS analysis (inductively coupled plasma-mass spectrometry).

In particular, the submicron silicon particles can be found to have no more than about 1 parts per million by weight (ppm) of metal contaminants, in further embodiments no more than about 900 parts per billion by weight (ppb) and in additional embodiments no more than about 700 ppb of total metal contaminants. For semiconductor applications, iron can be a contaminant of particular concern. With improved particle synthesis, handling and contaminant removal procedures, particles can be dispersed with no more than about 200 ppb of iron, in further embodiments, no more than about 100 ppb and in additional embodiments from about 15 ppb to about 75 ppb of iron contaminants with respect to the particle weight. A person of ordinary skill in the art will recognize that additional ranges of contaminant levels within the explicit ranges above are contemplated and are within the present disclosure. The low contaminant levels allows for the production of particles with low dopant levels of dopants, such as boron or phosphorous, in which the low dopant levels can be effective of tuning the electronic properties of particles in a meaningful way that cannot be achieved at higher contaminant levels.

To achieve the very low contaminant levels, the particles can be synthesized in a laser pyrolysis apparatus sealed from the ambient atmosphere and appropriately cleaned and purged prior to the synthesis. Highly pure gaseous reactants can be used for the silicon precursors as well as for the dopant precursors. The particles can be collected and handled in a glove box to keep the particles free from contaminants from the ambient atmosphere. Very clean polymer containers, such as polyfluoroethylene containers, can be used for placement of the particles. For the formation of inks, the particles can be dispersed in very pure solvents within clean vessels within a glove box or clean room. With meticulous attention to all aspects of the process, the high purity levels described herein have been and generally can be achieved. The production of silicon particles with clean handling procedures is described further in copending U.S. patent application Ser. No. 13/070,286 to Chiruvolu et al., entitled “Silicon/Germanium Nanoparticle Inks, Laser Pyrolysis Reactors for the Synthesis of Nanoparticles and Associated Methods,” incorporated herein by reference.

The size of the dispersed particles in a liquid can be referred to as the secondary particle size. The primary particle size is roughly the lower limit of the secondary particle size for a particular collection of particles, so that the average secondary particle size can be approximately the average primary particle size if the primary particles are substantially unfused and if the particles are effectively completely dispersed in the liquid, which involves solvation forces that successfully overcome the inter-particle forces.

The secondary particle size may depend on the subsequent processing of the particles following their initial formation and the composition and structure of the particles. In particular, the particle surface chemistry, properties of the dispersant, the application of disruptive forces, such as shear or sonic forces, and the like can influence the efficiency of frilly dispersing the particles. Ranges of values of average secondary particle sizes are presented below with respect to the description of dispersions. Secondary particles sizes within a liquid dispersion can be measured by established approaches, such as dynamic light scattering. Suitable particle size analyzers include, for example, a Microtrac UPA instrument from Honeywell based on dynamic light scattering, a Horiba Particle Size Analyzer from Horiba, Japan and ZetaSizer Series of instruments from Malvern based on Photon Correlation Spectroscopy. The principles of dynamic light scattering for particle size measurements in liquids are well established. Values of secondary particle sizes are provided below.

As noted above, laser pyrolysis can also be effective for the production of uniform nanoparticles of silicon oxide (silica). To form silica, an oxygen source, such as O₂, can be included in the reactant flow along with the silicon precursor. High uniformity with respect to primary particle size and desirable distributions of secondary particle size have been observed with silica nanoparticles formed using laser pyrolysis. These particles have been used to form good quality inks as described in the '872 patent cited above.

Dopants can be introduced to vary properties of the resulting particles for elemental silicon as well as silica. In general, any reasonable element can be introduced as a dopant to achieve desired properties. For example, dopants can be introduced to change the electrical properties of the particles. In particular, As, Sb and/or P dopants can be introduced into the elemental silicon particles to form n-type semiconducting materials in which the dopant provide excess electrons to populate the conduction bands, and B, Al, Ga and/or In can be introduced to form p-type semiconducting materials in which the dopants supply holes. P and B are used as dopants in the Examples below.

In some embodiments, one or more dopants can be introduced into the elemental silicon particles or silica particles in concentrations from about 1.0×10⁻⁷ to about 15 atomic percent relative to the silicon atoms, in further embodiments from about 1.0×10⁻⁵ to about 5.0 atomic percent and in further embodiments from about 1×10⁻⁴ to about 1.0 atomic percent relative to the silicon atoms. Both the low dopant levels and the high dopant levels are of interest in appropriate contexts. For the low dopant levels to be of particular usefulness, the particle should be pure. For small particles, the low dopant levels essentially can correspond with less than one dopant atom per particle on average. In combination with the high purity that has been achieved for the particles, low dopant levels from about 1.0×10⁻⁷ to about 5.0×10⁻³ correspond with difficult to achieve yet potentially useful materials. In some embodiments, high dopant levels are of particular interest, and the highly doped particles can have a dopant concentration from about 0.1 atomic percent to about 15 atomic percent, in other embodiments from about 0.25 atomic percent to about 12 atomic percent, and in further embodiments from about 0.5 atomic percent to about 10 atomic percent. A person of ordinary skill in the art will recognize that additional ranges within the explicit dopant level ranges are contemplated and are within the present disclosure.

### Dispersions and Properties of the Dispersions

Desirable silicon inks are formed by processing initial stable dispersions of silicon nanoparticles to adjust the properties to be appropriate for a selected deposition approach. Dispersions of particular interest comprise a dispersing liquid or solvent and silicon nanoparticles dispersed within the liquid along with optional additives. In appropriate embodiments, silicon particles from laser pyrolysis are collected as a powder, and dispersed in a solvent or solvent blend by mixing, although suitable silicon nanoparticles from other sources can be used if of sufficient quality. The dispersion can be stable with respect to avoidance of settling over a reasonable period of time, generally at least an hour, without further mixing. A dispersion can be used as an ink and the properties of the ink can be adjusted based on the particular deposition method. For example, in some embodiments, the viscosity of the ink is adjusted for the use in a particular coating or printing application, and particle concentrations and additives can provide some additional parameters to adjust the viscosity and other ink properties. In some embodiments, the particles can be formed with concentrated dispersions with desirable fluid properties without surface modifying the particles with organic compounds. As noted above, the lack of surface modification with organic compounds excludes references to solvent-based interactions. In general, the solvents may interact with the particle surfaces with varying degrees of interactions that are distinct from the inclusion of distinct surface modifying agents that form strong and effectively durable chemical modification of the particle surfaces. The availability to form stable dispersions with small secondary particle sizes provides the ability to form certain inks that are not otherwise possible.

Furthermore, it can be desirable for the silicon nanoparticles to be uniform with respect to particle size and other properties. Specifically, it is desirable for the particles to have a uniform primary particle size and for the primary particles to be sufficiently unfused based on the primary particle size, although for very small particles, e.g., less than 15 nm average primary particle size, some fusing is less significant with respect to ink properties. Then, the particles generally can be dispersed to yield a small and relatively uniform secondary particle size in the dispersion, e.g. as reflected in a narrow distribution of sizes as measured by light scattering. The formation of a good dispersion with a small secondary particle size can be facilitated through the matching of the surface chemistry of the particles with the properties of the dispersing liquid. The surface chemistry of particles can be influenced during synthesis of the particles as well as following collection of the particles. For example, the formation of dispersions with polar solvents is facilitated if the particles have polar groups on the particle surface.

As described herein, suitable approaches have been found to disperse dry silicon nanoparticle powders and to form high quality silicon inks and the like for deposition. In some embodiments, the particle can be surface modified with an organic compound to change the surface properties of the particles in a dispersion, but in some embodiments of particular interest, the particles are not covalently surface modified with an organic compound since the lack of surface modification can provide advantages with respect to properties for certain applications and to simply processing. Thus, for some embodiments, significant advantages are obtained by forming dispersions of particles without surface modification. Using one or more of the processing approaches described herein, inks can be formed that can be deposited using convenient coating and printing approaches based on established commercial parameters. Thus, the advantages of vapor-based particle synthesis can be combined with desirable solution based processing approaches with highly dispersed particles to obtain desirable dispersions and inks, which can be formed with doped particles.

With respect to silicon dispersions, the dispersions can have silicon nanoparticle concentrations from low concentrations to about 30 weight percent. In general, the secondary particles size can be expressed as a cumulant mean, or Z-average particle size, as measured with dynamic light scattering (DLS). The Z-average particle size is based on a scattering intensity weighted distribution as a function of particle size. The scattering intensity is a function of the particle size to the 6th power so that larger particles scatter much more intensely. Evaluation of this distribution is prescribed in ISO International Standard 13321, Methods for Determination of Particle Size Distribution Part 8: Photon Correlation Spectroscopy, 1996, incorporated herein by reference. The Z-average distributions are based on a single exponential fit to time correlation functions. However, small particles scatter light with less intensity relative to their volume contribution to the dispersion. The intensity weighted distribution can be converted to a volume-weighted distribution that is perhaps more conceptually relevant for evaluating the properties of a dispersion. For nanoscale particles, the volume-based distribution can be evaluated from the intensity distribution using Mie Theory. The volume-average particle size can be evaluated from the volume-based particle size distribution. Further description of the manipulation of the secondary particle size distributions can be found in Malvern Instruments—DLS Technical Note MRK656-01, incorporated herein by reference. As a general matter, due to the scaling of volume average particle sizes by the cube of the particle diameter and the scattering intensity average (Z-average) by the sixth power of the average particle size, these measurements significantly provide emphasis to larger particles over smaller particles.

In general, if processed appropriately, for dispersions with well dispersed particles and little fusing of the primary particles, the Z-average secondary particle size can be no more than a factor of 5 times the average primary particle size, in further embodiments no more than about 4 times the average primary particle size and in additional embodiments no more than about 3 times the average primary particle size. For primary particles that exhibit some fusing, the absolute value of the Z-average dispersed particle size is still very significant for the processing properties of the silicon particle distributions. In some embodiments, the Z-average particle size is no more than about 1 micron, in further embodiments no more than about 250 nm, in additional embodiments no more than about 200 nm, in some embodiments from about 40 nm to about 150 nm, in other embodiments from about 45 nm to about 125 nm, in further embodiments from about 50 nm to about 100 nm. In particular, for some printing applications, it is observed that good printing properties are generally correlated with Z-average particle sizes of no more than about 200 nm. A person of ordinary skill in the art will recognize that additional ranges of secondary particle sizes within the explicit ranges above are contemplated and are within the present disclosure.

With respect to the particle size distribution, in some embodiment, essentially all of the secondary particles can have a size distribution from scattering results with effectively no intensity corresponding to more than 5 times the Z-average secondary particle size, in further embodiments no more than about 4 times the Z-average particle size and in other embodiments no more than about 3 times the Z-average particle size. Furthermore, the DLS light scattering particle size distribution can have in some embodiments a full width at half-height of no more than about 50 percent of the Z-average particle size. Also, the secondary particles can have a distribution in sizes such that at least about 95 percent of the particles have a diameter greater than about 40 percent of the Z-average particle size and less than about 250 percent of the Z-average particle size. In further embodiments, the secondary particles can have a distribution of particle sizes such that at least about 95 percent of the particles have a particle size greater than about 60 percent of the Z-average particle size and less than about 200 percent of the Z-average particle size. A person of ordinary skill in the art will recognize that additional ranges of particle sizes and distributions within the explicit ranges above are contemplated and are within the present disclosure.

In general, the surface chemistry of the particles influences the process of forming the dispersion. In particular, it is easier to disperse the particles to form smaller secondary particle sizes if the dispersing liquid and the particle surfaces are compatible chemically, although other parameters such as density, particle surface charge, solvent molecular structure and the like also directly influence dispersability. In some embodiments, the liquid may be selected to be appropriate for the particular use of the dispersion, such as for a printing process. For silicon synthesized using silanes, the resulting silicon generally is partially hydrogenated, i.e., the silicon includes some small amount of hydrogen in the material. It is generally unclear if this hydrogen or a portion of the hydrogen is at the surface as Si—H bonds. However, the presence of a small amount of hydrogen does not presently seem particularly significant. However, it is found that silicon particles formed by laser pyrolysis are suitable for forming good dispersions in appropriately selected solvents without modifying the particles with chemically bonded organic compounds.

In general, the surface chemistry of the particles can be influenced by the synthesis approach, as well as subsequent handling of the particles. The surface by its nature represents a termination of the underlying solid state structure of the particle. This termination of the surface of the silicon particles can involve truncation of the silicon lattice. The termination of particular particles influences the surface chemistry of the particles. The nature of the reactants, reaction conditions, and by-products during particle synthesis influences the surface chemistry of the particles collected as a powder during flow reactions. The silicon can be terminated, for example, with bonds to hydrogen, as noted above. In some embodiments, the silicon particles can become surface oxidized, for example through exposure to air. For these embodiments, the surface can have bridging oxygen atoms in Si—O—Si structures or Si—O—H groups if hydrogen is available during the oxidation process. By preventing exposure to the ambient atmosphere, surface oxidation of the particles can be substantially reduced to no more than about 2 weight percent in the particles.

In some embodiments, the surface properties of the particles can be modified through surface modification of the particles with a surface modifying composition chemically bonded to the particle surfaces. However, in some embodiments of particular interest, the particles are not surface modified so that unmodified particles are deposited for further processing. In appropriate embodiments, surface modification of the particles can influence the dispersion properties of the particles as well as the solvents that are suitable for dispersing the particles. Some surface active agents, such as many surfactants, act through non-bonding interactions with the particle surfaces, and these processing agents are described further below. In some embodiments, desirable properties, especially dispersability in otherwise unavailable solvents, can be obtained through the use of surface modification agents that chemically bond to the particle surface. The surface chemistry of the particles influences the selection of surface modification agents. The use of surface modifying agents to alter the silicon particle surface properties is described further in published U.S. patent application 2008/0160265 to Hieslmair et al., entitled “Silicon/Germanium Particle Inks, Doped Particles, Printing, and Processes for Semiconductor Applications,” incorporated herein by reference.

While surface modified particles can be designed for use with particular solvents, it has been found that desirable inks can be formed without surface modification at high particle concentrations and with good deliverability. This is found to be true even when surface oxidation is avoided so that the surface of the particles is essentially devoid of surface passivation. The ability to form desired inks without surface modification can be useful for the formation of desired devices, especially semiconductor based devices, with a lower level of contamination.

As described above, the formation of desirable inks with improved deposition properties generally comprises a sonication step and a centrifugation step, and in some embodiments, a plurality of one or both of these steps. In particular, it has been found to be useful to perform a plurality of centrifugation steps to improve the quality of the resulting inks. Specifically, the supernatant of a first centrifugation step can be centrifuged a second time with the second supernatant used to form the silicon ink, and the centrifugation process can be repeated a third time or more if desired.

For small silicon nanoparticles, it has been found significantly advantageous to perform an initial mixing step, a centrifugation step and a subsequent sonication step. Initial mixing is advantageous in that it can aid in the formation of good initial dispersions from as-synthesized powder. A good initial dispersion of the particles prior to further processing can facilitate the subsequent processing steps and can desirably affect the properties of the target ink. The initial dispersion of the as-synthesized particles generally comprises the selection of a solvent that is relatively compatible with the particles based on the surface chemistry of the particles. The as-synthesized particles are added to a solvent and initially mixed. In general, it is desirable for the particles to be well dispersed, although the particles do not need to be stably dispersed initially if the particles are subsequently transferred to another liquid.

Initial mixing can include mechanical mixing and/or sonication mixing. Mechanical mixing can include, but is not limited to, beating, stirring, and/or centrifugal planetary mixing. In some embodiments, centrifugal planetary mixing has been shown to be particularly effective as a mechanical mixing approach in reducing particle agglomeration, although other initial mixing methods can also desirably reduce particle agglomeration. The procedure for performing the initial mixing can significantly influence the concentration of the resulting ink. In particular, the initial mixing step influences the amount of particulates that remain suspended following the centrifugation step. Initial mixing can comprise a plurality of distinct mixing steps, which may or may not be similar in quality.

In centrifugal planetary mixing, the material to be mixed is placed in a container that is rotated about its own axis and the container itself rotates around another axis of the mixer to generate a spiral convection to mix the contents of the container. The mixer provides strong mixing conditions without the application of strong shear, such as in a twin screw extruder. Centrifugal planetary mixers are available from commercial sources such as THINKY USA, Inc. (Laguna Hills, Calif.). In some embodiments, a mixture of as-synthesized particles and solvent is initially mixed in a centrifugal planetary mixer at between about 200 rpm to about 10,000 and, in other embodiment, from about 500 rpm to about 8000 rpm. In some embodiments, a mixture as as-synthesized particles initially mixed in a centrifugal planetary mixer, for example, for up to about an hour and, in other embodiments, from about 1 min. to about 30 min. A person of ordinary skill in the art will recognize that additional ranges of centrifugation frequencies and times are within the explicit ranges herein are contemplated and are within the present disclosure.

Sonication generally can include, but is not limited to, bath sonication, probe sonication, ultrasonic cavitation mixing, combinations thereof or the like. Sonication processes involve the propagation of sound waves, generally at ultrasonic frequencies, that result in cavity formation in the liquid and the violent collapse of the resulting bubbles. A range of commercial sonication devices are available. Bath and probe sonication can also allow for convenient temperature control during initial mixing by controlling the temperature of the surrounding bath. In some embodiments, however, it has been observed that bath sonication at a low temperatures (e.g. between about 4° C. to about 10° C.) can lead to gelation of the ink after later processing steps. In other embodiments, bath sonication at low temperatures does not lead to ink gelation during processing, as described in the Examples below, and some improvements are observed with low temperature sonication. In some embodiments, a mixture is sonicated for no more than about 20 hrs, in other embodiments for no more than about 5 hrs, and in further embodiments from about 5 min. to about 30 min. A person of ordinary skill in the art will recognize that additional ranges of centrifugation frequencies and times are within the explicit ranges herein are contemplated and are within the present disclosure.

In general, the dispersion can be centrifuged to improve the properties of the dispersion. It has been found that centrifugation of silicon particle dispersions can be useful for the formation of the highly pure dispersions with very low metal contamination described herein. The centrifugation parameters can be selected such that at least a reasonable fraction of the silicon nanoparticles remain dispersed, but contaminants and more poorly dispersed solid components settle to the bottom of the centrifuge container.

To obtain greater improvement in the dispersion properties, centrifugation can comprise multiple centrifugation steps, with each subsequent step performed with the same or different centrifugation parameters as the preceding step. In some embodiments, after each centrifugation step, the supernatant can be decanted or similarly separated from the settled contaminants and subsequently centrifuged in the subsequent centrifugation step. Additional mixing or other processing steps can be performed between centrifugation steps for embodiments involving multiple centrifugation steps. After centrifugation for further processing or use of the inks, the supernatant can be decanted or similarly separated from the settled contaminants for further processing. Multiple-step and single-step centrifugation is demonstrated in the Examples, below. In some embodiments, a dispersion is centrifuged at 3000 revolutions per minute (rpm) to 15000 rpm, in further embodiments from about 4000 rpm to about 14000 rpm and in other embodiments form about 5000 rpm to about 13000 rpm. In some embodiments, a dispersion is centrifuged for about 5 minutes to about 2 hours, in further embodiments from about 10 minutes to about 1.75 hours and in other embodiments from about 15 minutes to about 1.5 hours. A person of ordinary skill in the art will recognize that additional ranges of centrifugation frequencies and times are within the explicit ranges herein are contemplated and are within the present disclosure.

After centrifugation, it can be desirable to further subject the dispersion to a post-centrifugation sonication, especially for silicon nanoparticles with an average primary particle size of no more than about 15 nm. It has been found that sonication after centrifugation can aid in formation of a higher quality ink if the silicon nanoparticles have an especially small primary particle size. Post-centrifugation sonication can comprise one or more selected forms of sonication as described above. With respect to post-centrifugation bath sonication, in some embodiments a dispersion is sonicated for no more than about 5 hr., in other embodiments from about 5 min. to about 3.5 hr, in further embodiments from about 10 min. to about 2 hr., and in yet other embodiments, from about 15 minutes to about 1.5 hr. A person of ordinary skill in the art will recognize that additional ranges within the explicit ranges above are contemplated and are within the present disclosure. Post-centrifugation sonication can be performed at the temperature ranges and with sonication frequencies as discussed above. Whether or not the ink is subjected to post-centrifugation sonication, the ink can be subjected to centrifugal planetary mixing or the like to homogenize the sample.

Furthermore, it has been discovered that measurements of properties, such as through light scattering measurements, of the static dispersion alone does not seem to provide adequate characterization of printing characteristics of the inks. Specifically, rheological measurements also provide significant information related to the deposition characteristics of the inks which can correspond to print quality. Rheology relates to the flow properties of a liquid. Thus, in principle, the theological measurements provide additional information that is not obtained from the light scattering measurements of a static particle dispersion. The results described herein provide evidence that the rheological measurements provide significant information related to ink properties that are not reflected in light scattering measurements.

Rheological measurements include measurements of viscosity. Viscosity is a measure of a fluid's resistance to shear stress. In general, the rate at which a fluid deforms (i.e. sheer rate) in response to an applied force (i.e. shear stress) determines the viscosity of the fluid being studied. For Newtonian fluids, the viscosity is constant such that the shear rate scales with the shear stress. For non-Newtonian fluids, the viscosity varies non-linearly with the shear stress. An ink's viscosity can be measured using a rheometer. In some embodiments of a rheometer, the liquid to be studied is placed in the annulus between a drive cylinder and a free cylinder. A shear stress is then applied to the ink by rotating the drive cylinder. The moving ink in the annulus, in response to the applied shear stress, causes the free cylinder to begin rotating. The shear rate and, therefore the viscosity of the fluid, can then be calculated from the rotational frequency of the free cylinder. Furthermore, because the applied shear stress can be adjusted by adjusting the rotational frequency of the drive cylinder, a rheometer can be used to obtain the viscosity of non-Newtonian fluids over a wide range of shear stresses. Rheometers are widely available from commercial sources such as Brookfield Engineering Laboratories, Inc. (Middleboro, Mass.).

For particular applications, there may be fairly specific target properties of the inks as well as the corresponding liquids used in formulating the inks. At an appropriate stage in the dispersion process, it can be desirable to change the solvent in the dispersion. It can also be desirable to increase the particle concentration of a dispersion/ink relative to an initial concentration used to form a good dispersion.

Solvent compositions can be generally changed at any convenient point in the processing as well as at multiple points in the overall processing. For example, in some embodiments, a solvent blend at a selected concentration can be formed between the initial mixing step and the centrifugation step, while in other embodiments a solvent blend can be formulated after a centrifugation step before a post-centrifugation sonication step. Also, additional mixing steps can be included in combination with the solvent changes, and solvent modification can be performed between multiple centrifugation steps. One approach for changing solvents involves the addition of a liquid that destabilizes the dispersion. The liquid blend then can be substantially separated from the particles through decanting or the like. The particles are then re-dispersed in the newly selected liquid. This approach for changing solvents is discussed in published U.S. patent application 2008/016065 to Hieslmair et al., entitled “Silicon/Germanium Particle Inks, Doped Particles, Printing and Processes for Semiconductor Applications,” incorporated herein by reference.

With respect to the increase of particle concentration, solvent can be removed through evaporation to increase the concentration. This solvent removal generally can be done appropriately without destabilizing the dispersion. A lower boiling solvent component can be removed preferentially through evaporation. If the solvent blend forms an azeotrope, a combination of evaporation and further solvent addition can be used to obtain a target solvent blend. Solvent blends can be particularly useful for the formation of ink compositions since the blends can have multiple liquids that each contribute desirable properties to the ink. In some embodiments, a low boiling temperature solvent component can evaporate relatively quickly after printing to stabilize the printed ink prior to further processing and curing. A higher temperature solvent component can be used to adjust the viscosity to limit spreading after printing. Thus, for many printing applications, solvent blends are desirable. The overall solvent composition can be adjusted to yield desired ink properties and particle concentrations.

For appropriate embodiments, the design of a solvent blend can be based on the ability to maintain a good dispersion after the initial formation of the dispersion. Thus, a desirable approach for the formation of inks with desired properties is to form a good dispersion of the particles and to maintain the good dispersion of the particles through the blending of solvents. The blend of solvents is selected such that the different liquids combine to fond a single phase through the miscibility or solubility of the liquids with respect to each other. In some embodiments, it can be desirable to form dispersions by initially dispersing the as-synthesized particles in a blend of solvents. In some embodiments, an additional solvent can be added to the dispersion after initial mixing. Generally, a solvent can be added to a dispersion without destabilizing the dispersion. However, it can also be desirable to further mix a dispersion after addition of a solvent.

The dispersions can be formulated for a selected application. The dispersions can be characterized with respect to composition as well as the characterization of the particles within the dispersions. In general, the term ink is used to describe a dispersion that is subsequently deposited using a coating or printing technique, and an ink may or may not include additional additives to modify the ink properties.

As used herein, stable dispersions have no settling without continuing mixing after one hour. In some embodiments, the dispersions exhibit no settling of particles without additional mixing after one day and in further embodiments after one week, and in additional embodiments after one month. In general, dispersions with well dispersed particles can be formed at concentrations of at least up to 30 weight percent inorganic particles. Generally, for some embodiments it is desirable to have dispersions with a particle concentration of at least about 0.05 weight percent, in other embodiments at least about 0.25 weight percent, in additional embodiments from about 0.5 weight percent to about 25 weight percent and in further embodiments from about 1 weight percent to about 20 weight percent. A person of ordinary skill in the art will recognize that additional ranges of stability times and concentrations within the explicit ranges above are contemplated and are within the present disclosure.

The dispersions can include additional compositions besides the silicon particles and the dispersing liquid or liquid blend to modify the properties of the dispersion to facilitate the particular application. For example, property modifiers can be added to the dispersion to facilitate the deposition process. In particular, for screen printing pastes, polymer additives can significantly improve the printing qualities.

In general, polymeric additives can promote desirable ink compositions. Within the ink composition, polymeric additives can function as dispersants, binders, and/or rheology modifiers. As a dispersant, polymeric additives can promote good dispersions by desirably effecting the particle/particle and particle/solvent interactions. As rheology modifiers, polymeric additives can desirably alter the viscosity and/or surface tension of an ink composition. For certain printing applications, such as screen printing, polymer additives can be particularly desirable. For example, using well dispersed ink compositions with appropriately selected rheological properties, screen printing inks can be formulated to inhibit screen clogging during multiple print cycles. Polymer additives can include, for example, polymers with polar groups, such as hydroxide groups, that are soluble in alcohols. Suitable polymers with polar functional groups include, for example, cellulose ethers, such as methyl cellulose, ethyl cellulose, hydroxyethyl cellulose, carboxymethyl cellulose, benzyl cellulose and the like. Desirable paste properties resulting from the use of ethyl cellulose is described further in the example below. Other polymer binders have been used for screen printing pastes for ceramic film formation, as described in U.S. Pat. No. 6,808,577 to Miayazaki et al., entitled “Monolithic Ceramic Electronic Component and Production Process Therefor, and Ceramic Paste and Production Process Therefor” incorporated herein by reference. Other suitable polymers that can be removed during sintering of the paste include, for example, polyacetals, such as polyvinyl butyral and polybutyl butyral, polymethacrylates, vinylidenes, polyethers, epoxy resins, polyurethanes, polyamides, polyimides, polyamidoimides, polyesters, polysulfones, liquid crystal polymers, polyimidazoles and polyoxasolines.

Blends of different polymer additives can also be used in ink formulations to obtain desired properties. In general, the one or more polymer additives can be selected to be compatible with the solvent system selected to stabilize the silicon nanoparticle dispersion, while providing desirable rheological properties. In some embodiments, the ink can have a polymer additive concentration from about 0.25 weight percent to about 20 weight percent, in other embodiments from about 1 weight percent to about 15 weight percent and in further embodiments from about 2 weight percent to about 10 weight percent. A person of ordinary skill in the art will recognize that additional ranges of polymer additive concentrations within the explicit ranges above are contemplated and are within the present disclosure.

In some embodiments, cationic, anionic, zwitter-ionic and/or nonionic surfactants can be helpful in particular applications. In some applications, the surfactant further stabilizes the particle dispersions. For these applications, the selection of the surfactant can be influenced by the particular dispersing liquid as well as the properties of the particle surfaces. In general, surfactants are known in the art. Furthermore, the surfactants can be selected to influence the wetting or beading of the dispersion/ink onto the substrate surface following deposition of the dispersion. In some applications, it may be desirable for the dispersion to wet the surface, while in other applications it may be desirable for the dispersion to bead on the surface. The surface tension on the particular surface is influenced by the surfactant. Also, blends of surfactants can be helpful to combine the desired features of different surfactants, such as improve the dispersion stability and obtaining desired wetting properties following deposition. In some embodiments, the dispersions can have surfactant concentrations from about 0.01 to about 5 weight percent, and in further embodiments from about 0.02 to about 3 weight percent.

The use of non-ionic surfactants in printer inks is described further in U.S. Pat. No. 6,821,329 to Choy, entitled “Ink Compositions and Methods of Ink-Jet Printing on Hydrophobic Media,” incorporated herein by reference. Suitable non-ionic surfactants described in this reference include, for example, organo-silicone surfactants, such as SILWET™ surfactants from Crompton Corp., polyethylene oxides, alkyl polyethylene oxides, other polyethylene oxide derivatives, some of which are sold under the trade names, TERGITOL™, BRIJ™, TRITON™, PLURONIC™, PLURAFAC™, IGEPALE™, and SULFYNOL™ from commercial manufacturers Union Carbide Corp., ICI Group, Rhone-Poulenc Co., Rhom & Haas Co., BASF Group and Air Products Inc. Other nonionic surfactants include MACKAM™ octylamine chloroacetic adducts from McIntyre Group and FLUORAD™ fluorosurfactants from 3M. The use of cationic surfactants and anionic surfactants for printing inks is described in U.S. Pat. No. 6,793,724 to Satoh et al., entitled “Ink for Ink-Jet Recording and Color Ink Set,” incorporated herein by reference. This patent describes examples of anionic surfactants such as polyoxyethylene alkyl ether sulfate salt and polyoxyalkyl ether phosphate salt, and examples of cationic surfactants, such as quaternary ammonium salts.

Viscosity modifiers can be added to alter the viscosity of the dispersions. Suitable viscosity modifiers include, for example soluble polymers, such as polyacrylic acid, polyvinyl pyrrolidone and polyvinyl alcohol. Other potential additives include, for example, pH adjusting agents, antioxidants, UV absorbers, antiseptic agents and the like. These additional additives are generally present in amounts of no more than about 5 weight percent. A person of ordinary skill in the art will recognize that additional ranges of surfactant and additive concentrations within the explicit ranges herein are contemplated and are within the present disclosure.

For electronic applications, it can be desirable to remove organic components to the ink prior to or during certain processing steps such that the product materials are effectively free from carbon. In general, organic liquids can be evaporated to remove them from the deposited material. However, surfactants, surface modifying agents and other property modifiers may not be removable through evaporation, although they can be removed through heating at moderate temperature in an oxygen atmosphere to combust the organic materials.

The use and removal of surfactants for forming metal oxide powders is described in U.S. Pat. No. 6,752,979 to Talbot et al., entitled “Production of Metal Oxide Particles with Nano-Sized Grains,” incorporated herein by reference. The '979 patent teaches suitable non-ionic surfactants, cationic surfactants, anionic surfactants and zwitter-ionic surfactants. The removal of the surfactants involves heating of the surfactants to moderate temperatures, such as to 200° C. in an oxygen atmosphere to combust the surfactant. Other organic additives generally can be combusted for removal analogously with the surfactants. If the substrate surface is sensitive to oxidation during the combustion process, a reducing step can be used following the combustion to return the surface to its original state.

The viscosity of the dispersion/ink is dependent on the silicon particle concentration, the nature of the liquids as well as the presence of any other additives. Thus, there are several parameters that provide for adjustment of the viscosity, and these parameters can be adjusted together to obtain overall desired ink properties. In general, a selected coating or printing approach has an appropriate range of viscosity. Surface tension may also be a significant parameter for certain printing applications. For some desired ink formulations, the use of a solvent blend can provide for the rapid evaporation of a low boiling temperature solvent (boiling point approximately no more than about 165° C. and in other embodiments no more than about 160° C.) while using a higher boiling solvent (boiling point at least about 170° C. and in other embodiments at least about 175° C.) to control the viscosity. The high boiling solvent generally can be removed more slowly without excessive blurring of the printed image. After removal of the higher boiling temperature solvent, the printed silicon particles can be cured, or further processed into the desired device. The properties for silicon nanoparticle inks designed for certain coating or printing processes are described in more detail in the following. These printing techniques represent a significant range of desired viscosities from relatively low viscosity for inkjet inks, to moderate viscosities for gravure printing inks and high viscosities for screen print pastes.

Desirable spin-coating ink viscosities and surface tensions can be selected with respect to the desired properties of the target film. Film properties include, but are not limited to, film homogeneity and thickness. For some spin-coating embodiments, the dispersion/ink can have a viscosity from about 0.5 centipoises (cP) to about 150 cP, in further embodiments from about 1 to about 100 cP and in additional embodiments from about 2 cP to about 75 cP. In some embodiments, spin-coating dispersions/inks can have a surface tension from about 20 to about 100 dynes/cm. For some spray coating inks, the viscosity can be from 0.1 cP (mPa·s) to about 100 cP, in other embodiments from about 0.5 cP to about 50 cP and in further embodiments from about 1 cP to about 30 cP. A person of ordinary skill in the art will recognize that additional ranges of viscosity and surface tension within the explicit ranges above are contemplated and are within the present disclosure.

To achieve the target fluid properties, the compositions of the fluids can be correspondingly adjusted. For spray coating inks, the silicon particle concentrations are generally at least about 0.25 weight percent, in further embodiments at least about 2.5 weight percent and in additional embodiments from about 1 weight percent to about 15 weight percent. In some embodiments, the spray coating inks can comprise an alcohol and a polar aprotic solvent. The alcohol can be a relatively low boiling point solvent, such as isopropanol, ethanol, methanol or combinations thereof. In some embodiments, suitable aprotic solvents include, for example, N-methylpyrolidone, dimethylformamide, dimethylsulfoxide, methylethylketone, acetonitrile, ethylacetate and combinations thereof. In general, the ink can comprise from about 10 weight percent to about 70 weight percent alcohol and in further embodiments from about 20 weight percent to about 50 weight percent alcohol. Similarly, the ink can comprise from about 30 weight percent to about 80 weight percent polar aprotic solvent and in additional embodiments form about 40 weight percent to about 70 weight percent polar aprotic solvent. A person of ordinary skill in the art will recognize that additional concentration and property ranges within the explicit ranges above are contemplated and are within the present disclosure.

For screen printing, the formulations are prepared as a paste that can be delivered through the screen. The screens generally are reused repeatedly. The solvent systems for the paste should be selected to both provide desired printing properties and to be compatible with the screens to help avoid screen damaged and/or clogging by the paste. Suitable lower boiling point solvents with boiling points of no more than about 165° C. include, for example, isopropyl alcohol, cyclohexanone, dimethylformamide, acetone or combinations thereof. Suitable higher boiling point solvents with boiling points of at least about 170° C. include, for examples, ethylene glycol, propylene glycol, N-methylpyrrolidone, terpineols, such as α-terpineol, 2-(2-ethoxyethoxy)ethanol (Carbitol), glycol ethers, e.g., butyl cellosolve, or combinations thereof. The screen printing paste can further include a surfactant and/or a viscosity modifier.

In general, the screen printable ink or paste are very viscous at low shear and are non-Newtonian. In particular, the pastes have a high viscosity at low shear and a significantly decreased viscosity at high shear. This non-Newtonian behavior can be used effectively to control the printing process since the paste can be stable on the screen between print cycles and printed with the application of higher shear to deliver the ink through the screen to a substrate.

In some embodiments, the elemental silicon screen printing pastes can have an average viscosity at a shear of 2 s⁻¹, from about 3 Pa·s (Poise) to about 450 Pa·s, in further embodiments from about 4 Pa·s to about 350 Pa·s and in additional embodiments from about 5 Pa·s to about 300 Pa·s. Furthermore, the pastes can have an average viscosity at a shear of 1000 s⁻¹, of no more than about 2 Pa·s, in other embodiments from about 0.001 Pa·s to about 1.9 Pa·s, in further embodiments from about 0.01 Pa·s to about 1.8 Pa·s, and in additional embodiments from about 0.02 to about 1.5 Pa·s. The ratio of low shear to high shear average viscosities is also significant since the screen printing process relies on the change in viscosity. The ratio of low shear average viscosity to high shear average viscosity can be in some embodiments from about 5 to about 200, in further embodiments from about 10 to about 175 and in other embodiments from about 15 to about 150. A person of ordinary skill in the art will recognize that additional ranges of paste rheology parameters within the explicit ranges above are contemplated and are within the present disclosure.

Also, it is desirable for the screen printing paste to not change significantly with repeated printing. In general, the screen is loaded with paste to provide for a significant number of print steps. Printing can be simulated in a rheometer using a high shear period to simulate printing and low shear period to simulate a rest period between printing steps. Specifically, for the purposes of testing this stability, the paste can be subjected to 60 second high shear (1000 s⁻¹) period followed by 200 second low shear (2 s⁻¹) rest period, which is repeated. In general, it is desirable for the average viscosity of the ink during the post-printing rest period to be no less than about 70% of the pre-printing rest period average viscosity, and in further embodiments no less than 80% of the pre-printing ret period average viscosity. Also, after 20 print steps for the average viscosity to be at least about 50%, in some embodiments at least about 75%, in other embodiments at least about 90% of the initial pre-print average viscosity, and in further embodiments at least about the initial pre-print average viscosity. In the Examples below, the average viscosity increases with printing, which may be due to solvent evaporation. Apparatus configurations to reduce or eliminate significant solvent evaporation may further stabilize the paste viscosity with printing. A person of ordinary skill in the art will recognize that additional ranges of paste rheology parameters within the explicit ranges above are contemplated and are within the present disclosure.

The screen printable inks generally can have a silicon particle concentration from about 1 weight percent to about 25 weight percent silicon particles, in further embodiments from about 1.5 weight percent to about 20 weight percent silicon particles, in additional embodiments from about 2 weight percent to about 18 weight percent and in other embodiments from about 2.5 weight percent to about 15 weight percent silicon particles. Also, the screen printable inks can have from 0 to about 10 weight percent lower boiling solvent, in further embodiments from about 0.5 to about 8 and in other embodiments from about 1 to about 7 weight percent lower boiling solvent as well as in some embodiments from about 65 weight percent to about 98 weight percent and in further embodiments from about 70 weight percent to about 95 weight percent higher boiling solvent. The description of screen printable pastes for the formation of electrical components is described further in U.S. Pat. No. 5,801,108 to Huang et al., entitled “Low Temperature Curable Dielectric Paste,” incorporated herein by reference, although the dielectric paste comprises additives that are not suitable for the semiconductor pastes/inks described herein. A person of ordinary skill in the art will recognize that additional ranges of composition for silicon pastes within the explicit ranges above are contemplated and are within the present disclosure.

The property ranges of inks suitable for gravure printing are intermediate between the properties of inkjet inks and screen printing pastes. The properties of gravure inks are described further in the '286 application cited above.

While the inks can comprise heavily doped silicon particles, it can be desirable to further include a liquid dopant source in the ink. Suitable liquid dopant sources include, for example, organophosphorus compounds (for example, phosphonates, such as etidronic acid and dimethyl methyl phosphonate, organophosphine oxide, organophosphanes, such as diphenylphosphine, or organophosphates, such as trioctyl phosphate), organoboron compounds (tetraphenylborate or triphenylboron), phosphoric acid, boric acid, combinations thereof or the like. In general, an ink can comprise no more than about 10 weight percent dopant composition as well as any and all subranges within this explicit range.

For dopant drive in applications, it can be desirable to include further components to the ink to facilitate the dopant drive in process. In particular, the ink can comprise a silicon oxide precursor, such as tetraethyl orthosilicate (TEOS). TEOS can be converted to silica in a hydrolysis reaction with water at an appropriate pH. A silica glass can facilitate dopant drive in from highly doped silicon particles into a silicon substrate through the at least partial isolation of the dopants from the vapor phase above the deposited particles and/or to increase solid-phase diffusion pathways to the wafer surface. The alternative or additional use of spin on glasses and silica sol-gels in silicon inks is described in copending U.S. provisional patent application 61/438,064 to Liu et al, entitled “Silicon Substrates With Doped Surface Contacts Formed From Doped Silicon Inks and Corresponding Processes,” incorporated herein by reference.

As noted above, a silicon nanoparticle ink can further comprise a silica etching agent. A traditional silica wet etching agent comprises an aqueous solution of hydrogen fluoride (HF), which can be buffered with ammonium bifluoride (NH₄HF₂) and/or ammonium fluoride (NH₄F). Hydrogen fluoride is soluble in alcohols, and ammonium fluoride is slightly soluble in alcohols. The concentrations of HF, and optionally of ammonium fluoride, can be selected to achieve the desired silica etching rate for the silicon ink. Note that the silica etching compositions can also be effective at etching thin layers of silicon nitride and silicon oxynitride. When the etching composition is referenced herein, it will be understood that the composition can be effective at these other etching functions even if not specifically mentioned in the context. In some embodiments, the ink can comprise at least about 1 weight percent silica etching agent. The silicon particle concentrations and concentrations of other ink components generally can be selected as described herein for other inks as appropriate for a particular deposition approach. For more rapid etching, the ink can comprise a saturated HF solution. Other useful etchants include, for example, ammonium fluoride, ammonium bifluoride, ethylenediamine-pyrocatechol, ethanolamine-gallic acid, tetraalkyl ammonium hydroxide and combinations thereof.

The silicon nanoparticle inks with the silica etchant can be used to apply doped or undoped silicon nanoparticle deposits onto a silicon substrate where the silicon substrate has an oxide layer, generally silicon oxide. Thus, a separate etching step may be eliminated. The silica etchant can etch through the oxide layer to expose the silicon surface under the oxide layer to the ink. In general, the inks can be deposited using the various coating and printing approaches described herein, such as screen printing, inkjet printing, spin coating, knife edge coating or the like. During further processing, the silica etching agents generally evaporate or decompose into gaseous components with heating to moderate temperatures. Therefore, the compositions can be used to etch through oxide layers and then heated to moderate temperatures to leave a silicon particle coating while evaporating the solvent and correspondingly removing the etchant. In some embodiments, the deposited inks can be heated to temperatures form about 50° C. to about 300° C. to evaporate the solvent and to remove the silica etchant.

Following the drying of the material, a silicon particle coating remains that can be used for dopant delivery and/or to form a silicon mass on a substrate similar to the silicon inks described in detail herein without a silica etchant. Thus, the ink materials with the combination of silica etchant and the silicon nanoparticles can be used to effectively etch through silicon oxide coatings to expose a silicon underlayer that is then in contact with the silicon nanoparticle deposit following drying of the as deposited material. The silicon nanoparticle deposits that remain after drying the ink deposits can be further processed to fuse the silicon nanoparticles and/or drive dopant atoms into the silicon substrate. Further processing to fuse the silicon atoms can be performed generally at a temperature from about 700° C. to about 1200° C.

In other embodiments, silica nanoparticles are combined with the silicon nanoparticles in the ink/dispersion. The relative amounts of silicon nanoparticles and silica nanoparticles can be selected based on the particular application of the ink, and the overall ranges of silicon nanoparticle concentrations described elsewhere herein can apply equally to these blended particle inks. In some embodiments, the ink can comprise at least about 0.01 weight percent silica, in further embodiments from about 0.025 to about 10 weight percent and in other embodiments from about 0.05 to about 5 weight percent silica. In some embodiments, the weight ratio of silica nanoparticles to silicon nanoparticles can be at least about 0.01, in further embodiments from about 0.025 to about 1.5 and in additional embodiments from about 0.05 to about 1. A person of ordinary skill in the art will recognize that additional ranges of silica concentrations and silica to silicon ratios within the explicit ranges above are contemplated and are within the present disclosure. The silicon nanoparticles, the silica nanoparticles, both the silicon nanoparticles and the silica nanoparticles or a portion thereof may be doped. The silica nanoparticles can be used to increase the viscosity of the inks as well as to assist with the formation of a more densely packed deposit that can facilitate dopant drive in.

The particular additives can be added in an appropriate order to maintain the stability of the particle dispersion. In general, the additives can be added after centrifuging the silicon nanoparticle dispersion. Some mixing is performed to disburse the additive through the ink composition. A person of ordinary skill in the art can select the additives and mixing conditions empirically based on the teachings herein.

### Coating and Printing Processes

The dispersions/inks can be deposited using a selected approach that achieves a desired distribution of the dispersion on a substrate. For example, coating and printing techniques can be used to apply the ink to a surface. Coating methods can be particularly efficient for uniformly covering large surface areas with an ink in a relatively short amount of time. Using selected printing approaches, patterns can be formed with moderate resolution. Coating and/or printing processes can be repeated to obtain a thicker deposit of ink and/or to form overlapping patterns. For example, the printing/coating can be repeated for a total of two printing/coating steps, three printing/coating steps, four printing/coating steps or more than four printing/coating steps. Suitable substrates include, for example, polymers, such as polysiloxanes, polyamides, polyimides, polyethylenes, polycarbonates, polyesters, combinations thereof, and the like, ceramic substrates, such as silica glass, and semiconductor substrates, such as silicon or germanium substrates. The composition of the substrates influences the appropriate range of processing options following deposition of the dispersion/ink as well as the suitable application for the resulting structure.

For many applications it is desirable to use a silicon substrate. Suitable silicon substrates include, for example, silicon wafers, which can be cut from silicon ingots, or other silicon structures, such as those known in the art. Silicon wafers are commercially available. In other embodiments, suitable substrates include silicon/germanium foils, as described in published U.S. Patent application 2007/0212510A to Hieslmair et al., entitled “Thin Silicon or Germanium Sheets and Photovoltaics Formed From Thin Sheets,” incorporated herein by reference.

Each printing/coating step may or may not involve a patterning. The ink may or may not be dried or partially dried between the respective coating and/or printing steps. Sequential patterned printing steps generally involve the deposition onto an initially deposited ink material. The subsequent deposits may or may not approximately align with the initially deposited material, and further subsequently deposited patterns of material may or may not approximately align with the previously deposited layers. Thus, multiple layers can be present only at a subset of the ink deposit. Following deposition, the deposited material can be further processed into a desired device or state.

Suitable coating approaches for the application of the dispersions include, for example, spin coatings, dip coating, spray coating, knife-edge coating, extrusion or the like. In general, any suitable coating thickness can be applied, although in embodiments of particular interest, coating thickness can range from about 50 nm to about 500 microns and in further embodiments from about 100 nm to about 250 microns. A person of ordinary skill in the art will recognize that additional ranges of thicknesses within the particular ranges above are contemplated and are within the present disclosure.

In knife-edge coating, a substrate is coated by depositing an ink onto the substrate surface with a selected thickness such that the dried and/or further processed coating has an ultimate desired thickness of the coating. A sharp edge is suspended over the substrate so that distance between the edge of the knife and the substrate surface corresponds to the selected initial thickness of the coating. The substrate is then moved relative to the knife such that as the substrate moves past the blade, the deposited ink is reduced to the desired thickness. Substrate movement rates can be selected based upon the desired quality of the formed film as well as on ink characteristics. For example, a coating rate that is too high can undesirably affect the formed coating due to an undesirable increase in ink pressure as it passes under the knife edge. Slower coating rates result in longer residence time of the ink on the surface and can lead to undesirable evaporation of solvent from ink prior to moving passed the knife edge. The selection of the substrate movement rate is based upon a balance of these and other factors, including but not limited to, desired coating thickness, ink viscosity, and knife blade geometry.

Spin coating can be particularly desirable for the formation of highly uniform thin films. Spin coatings involves the deposition of an ink onto at least a portion of substrate and spinning the substrate to coat the substrate surface with the deposited ink. The rotational frequency of the substrate as well as the spin coating time can be selected with reference to the ink viscosity as well as the desired uniformity and thickness of the resulting coating. The substrate can be spun at a single rotational frequency or it can be spun at successively different frequencies for the same or for a different amount of time. Suitable spin-coating apparatuses are widely available from commercial sources such as Laurell Technologies Corporation (North Whales, Pa.). In some embodiments, the substrate is spun at a frequency of about 200 rpm to about 6000 rpm, in other embodiments from about 800 rpm to about 5000 rpm, and in further embodiments from about 1200 rpm to about 4500 rpm. In some embodiments, the substrate is spun for about 5 seconds to about 8 min. and in other embodiment from about 10 sec. to about 4 min. It can be desirable to have an initial spin step at a lower rate followed by a target spin rate such that a more controlled coating process is achieved, and in general, a spin coating process can have more than two spin steps if desired. A person of ordinary skill in the art will recognize that additional ranges of rotation frequency and spin coating time within the explicit ranges above are contemplated and are within the present disclosure.

Similarly, a range of printing techniques can be used to print the dispersion/ink into a pattern on a substrate. Suitable printing techniques include, for example, screen printing, inkjet printing, lithographic printing, gravure printing and the like. The selection of the printing technique can be influenced by a range of factors including, for example, capital costs, ease of incorporation into an overall production process, processing costs, resolution of the printed structure, printing time and the like.

While various coating and printing approaches are suitable, inkjet printing offers desirable features for some applications with respect to speed, resolution and versatility with respect to real time selection of deposition patterning while maintaining speed and resolution. Practical deposition using inkjet printing with inorganic particles requires dispersion properties that involve both the techniques to form high quality silicon nanoparticle, such as with laser pyrolysis, along with the improved ability to form high quality dispersions from these particles. Thus, the particles produced using laser pyrolysis combined with the improved dispersion techniques provides for the formation of inks that are amenable to inkjet deposition.

Screen printing can offer desirable features for printing silicon inks for some applications. In particular, screen printing may already be tooled for a particular use. Thus, the substitution of the silicon inks for other materials in a production line may be performed with reduced capital expenses. Also, the pastes for screen printing may have a greater silicon particle concentration relative to concentrations suitable for other deposition approaches, although additives can be used to lower particle concentrations for certain target deposition thicknesses. The silicon particles and processes described herein are suitable for forming good quality pastes for screen printing as demonstrated in the examples below.

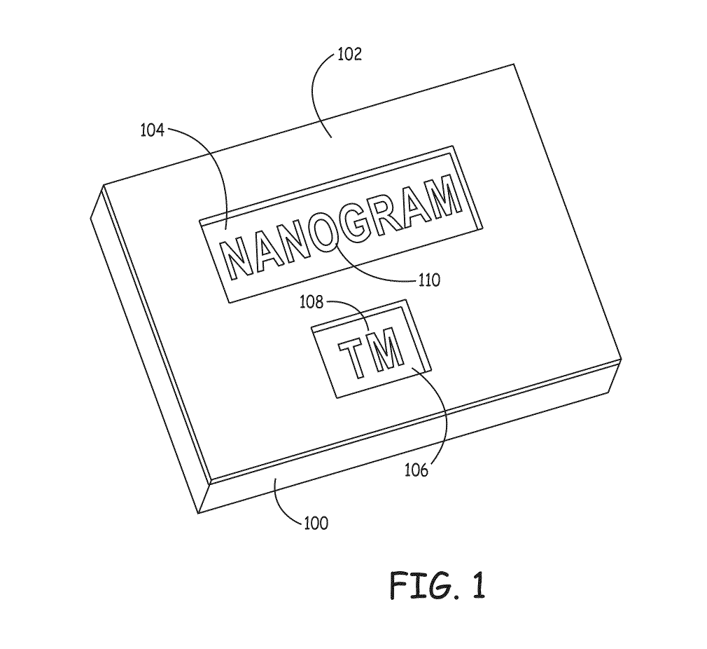

A representative printed substrate is shown in FIG. 1. In this embodiment, substrate 100 has an optional surface coating 102 with windows 104, 106 through coating 102 to expose a portion of the substrate surface. Silicon ink is printed to form deposits 108, 110 on the substrate surface. Suitable substrates include, for example, high purity silicon wafers and the like, although any reasonable substrate can be used as described above. A silicon dispersion/ink can be applied over the surface using the coating or printing techniques described above.

In general, following deposition, the liquid evaporates to leave the silicon particles and any other non-volatile components of the inks remaining. For some embodiments with suitable substrates that tolerates suitable temperatures and with organic ink additives, if the additives have been properly selected, the additives can be removed through the addition of heat in an appropriate atmosphere to remove the additives, as described above. Once the solvent and optional additives are removed, the silicon particles can then be processed further to achieve desired structures from the particles.

For example, the deposited silicon nanoparticles can be melted to form a cohesive mass of the silicon deposited at the selected locations. If a heat treatment is performed with reasonable control over the conditions, the deposited mass does not migrate significantly from the deposition location, and the fused mass can be further processed into a desired device. The approach used to sinter the silicon particles can be selected to be consistent with the substrate structure to avoid significant damage to the substrate during silicon particle processing. For example, laser sintering or oven based thermal heating can be used in some embodiments. Laser sintering and thermal sintering of silicon nanoparticles is described further in published U.S. patent application 2011/0120537 to Liu et al., entitled “Silicon Inks for Thin Film Solar Cell Formation, Corresponding Methods and Solar Cell Structures,” incorporated herein by reference. The use of highly doped silicon nanoparticles for dopant drive in applications is described further below.

### Semiconductor Applications

For solar cell, thin film transistor and other semiconductor applications, silicon particles can be used to form structures, such as doped elements, that can form a portion of a particular device. For particular applications, patterning or no patterning can be used as desired for a particular application. In some embodiments, the inks can be used to form layers or the like of doped or intrinsic silicon. The formation of silicon layers can be useful for formation or thin film semiconductor elements, such as on a polymer film for display, layers for thin film solar cells or other applications, or patterned elements, which can be highly doped for the introduction of desired functionality for thin film transistors, solar cell contacts or the like. In particular, doped silicon inks are suitable for printing to form doped contacts and emitters for crystalline silicon based solar cells, such as for selective emitter or back contact solar cell structures.

The formation of a solar cell junction can be performed, for example, using the screen printing of a silicon ink with thermal densification in which the processing steps are folded into an overall processing scheme. In some embodiments, doped silicon particles can be used as a dopant source that provides a dopant that is subsequently driven into the underlying substrate to for a doped region extending into the silicon material. Following dopant drive-in, the silicon particles may or may not be removed. Thus, the doped silicon particles can be used to form doped contacts for solar cells. The use of doped silicon particles for dopant drive-in is described further in copending U.S. patent application Ser. No. 13/113,287 to Liu et al (the “'287 application”), entitled “Silicon Substrates With Doped Surface Contacts Formed From Doped Silicon Inks and Corresponding Processes,” incorporated herein by reference.

For crystalline silicon based solar cells, doped silicon inks can be used to provide dopants for the formation of doped contacts and emitters along both surfaces of the cell or along the back surface of the cell, i.e., back contact solar cells. The doped contacts can form local diode junctions that drive collection of a photocurrent. Suitable patterning can be accomplished with the inks. Some specific embodiments of photovoltaic cells using thin semiconductor foils and back surface contact processing is described further in published U.S. patent application 2008/0202576 to Hieslmair (the '576 application), entitled “Solar Cell Structures, Photovoltaic Panels, and Corresponding Processes,” incorporated herein by reference.

Referring to FIGS. 2a and 2b, a representative embodiment of an individual photovoltaic cell is shown. The photovoltaic cell in these figures is a back contact only cell, although the inks described herein can be effectively used for other photovoltaic cell designs. Photovoltaic cell 200 comprises a semiconductor layer 210, a front surface passivation layer 220, a rear surface passivation layer 230, negative current collector 240, and positive current collector 250. FIG. 2b is a bottom-view of photovoltaic cell 200, showing only the semiconducting layer with deposited n-doped islands 260 and p-doped islands 270. For clarity, only the first two columns of doped islands are labeled, however successive columns are analogously doped with alternating dopant type. Collector 240 generally is in electrical contact with n-doped islands 260. Collector 250 generally is in electrical contact with p-doped islands 270. Holes can be created through rear surface passivation layer 230 in alignment with the doped islands 250, 260 and filed with current collector material to make electrical contact between doped islands 260, 270 and corresponding current collectors 240, 250. Each current collector has sections along opposite edges of the cell to connect the columns and to provide for connection of the current collectors. Other selected patterns can be used for the doped contacts in which the pattern provides for connections of commonly doped contacts with non-overlapping current collectors.

The '576 application describes forming shallow doped regions in some embodiments. These shallow doped regions can be conveniently formed by printing the doped silicon and using heat and/or light, such as from a laser or flash lamp, to fuse the doped silicon into corresponding doped contacts. This processing can further lead to dopant drive-in to supply dopant in the initial silicon material. Also, the doped silicon particles described herein can be also used to deliver the dopant atoms to the underlying silicon substrate. Also, other similar solar cell elements can be formed on other silicon or other semiconducting substrates for solar cell applications. Dopant drive-in and silicon particle fusing is described further in the '287 application cited above. If the silicon particles are used solely as a dopant source, the remains of the particles can be removed following processing if desired.

The inks can be effectively used to form thin film solar cells. In particular, nanocrystalline silicon can absorb significantly more visible light for a given thickness of material compared with highly crystalline silicon. In particular, for thin film solar cells, a stack with layers of p-type and n-type silicon are deposited, optionally with an intrinsic silicon layer between the doped layers to form a p-(i)-n diode junction across the cell. A plurality of stacks can be used if desired. The silicon inks described herein can be used to form one or more of the layers or portions thereof. The formation of thin film solar cells with silicon inks is described further in published U.S. patent application 2011/0120537 to Liu et al., entitled “Silicon Inks for Thin Film Solar Cell Formation, Corresponding Methods and Solar Cell Structures,” incorporated herein by reference.

The silicon inks can also be used for the formation of integrated circuits for certain applications. Thin film transistors (TFTs) can be used to gate new display structures including, for example, active matrix liquid crystal displays, electrophoretic displays, and organic light emitting diode displays (OLED). Appropriate elements of the transistors can be printed with silicon inks using conventional photolithographic approaches or for moderate resolution using inkjet printing or other suitable printing techniques. The substrates can be selected to be compatible with the processing temperatures for the ink.

The TFTs comprise doped semiconductor elements and corresponding interfaces. Thin film transistors used as electronic gates for a range of active matrix displays are described further in Published U.S. Patent Application number 2003/0222315A to Amundson et al., entitled “Backplanes for Display Applications, and Components for use Therein,” incorporated herein by reference. An n-type doped polycrystalline or amorphous silicon TFT active element with an anode common structure with an organic LED element is described further in U.S. Pat. No. 6,727,645 to Tsjimura et al., entitled “Organic LED Device,” incorporated herein by reference. OLED display structures are described further, for example, in published U.S. Patent Application 2003/0190763 to Cok et al., entitled “Method of Manufacturing a Top-Emitting OLED Display Device With Desiccant Structures,” incorporated herein by reference. Conventional photolithography techniques for the formation of TFTs is described further in U.S. Pat. No. 6,759,711 to Powell, entitled “Method of Manufacturing a Transistor,” incorporated herein by reference. These conventional photolithography approaches can be replaced with the printing approaches described herein. U.S. Pat. No. 6,759,711 further describes integration of TFTs with an active matrix liquid crystal display. The silicon nanoparticle inks described herein can be effectively used to print elements of a TFT with selected dopants.

Biochips are growing in use for diagnostic medical purposes. U.S. Pat. No. 6,761,816 to Blackburn et al., entitled “Printed Circuit Boards With Monolayers and Capture Ligands,” incorporated herein by reference. These biochip arrays have electrical circuits integrated with biological components so that automatic evaluations can be performed. The functional inks described herein can be used to form electrical components for these devices while biological liquids can be printed or otherwise deposited for the other components.

Radio-Frequency Identification (RFID) tags are gaining widespread use for loss prevention. These devices are desired to be small for less obtrusiveness and low cost. The silicon inks described herein can be used effectively to print RFIDs or components thereof. Systems for printing RFIDs on a roll-to-roll configuration are described further in published U.S. Patent Application serial number 2006/0267776A to Taki et al., entitled “RFID-Tag Fabricating Apparatus and Cartridge,” incorporated herein by reference.

To form a device component from the silicon particle deposit, the material can be heated. For example, the structure can be placed into an oven or the like with the temperature set to soften the particles such that fuse into a mass. This can be done, for example, by heating the substrate in an oven to relatively high temperatures, such as about 750° C. to 1250° C. to obtain a solid mass from the particles in intimate contact with the substrate surface. The time and temperature can be adjusted to yield a desired fusing and corresponding electrical properties of the fused mass. Appropriate approaches can be used to heat the surface of the substrate with the deposit. The heating of a silicon wafer with silicon nanoparticle ink coating in an oven or with a laser to form a fused mass is described further in the '287 application cited above. In alternative embodiments, a flash lamp, infrared lamp or the like can be used to provide rapid thermal processing of deposited silicon nanoparticles.

In some embodiments, improved control of the resulting doped substrate as well as energy saving can be obtained through the use of laser light to melt the silicon particles without generally heating the substrate or only heating the substrate to lower temperatures. Local high temperatures on the order of 1400° C. can be reached to melt the surface layer of the substrate as well as the silicon particles on the substrate. Generally, any intense source selected for absorption by the particles can be used, although excimer lasers or other lasers are a convenient UV source for this purpose. Excimer lasers can be pulsed at 10 to 300 nanoseconds at high fluence to briefly melt a thin layer, such as 20 nm to 1000 nm, of the substrate. Also, YAG lasers may be useful. Also, longer wavelength light sources such as green or infrared lasers can also be used to obtain greater depth penetration into the silicon deposit. This photonic curing process may be suitable for some lower melting substrates.

Thermal and light based fusing of silicon particles is described further in the '286 patent application cited above. Silicon particle fusing is also discussed in published U.S. Patent Application 2005/0145163A to Matsuki et al., entitled “Composition for Forming Silicon Film and Method for Forming Silicon Film,” incorporated herein by reference. In particular, this reference describes the alternative use of irradiation with a laser or with a flash lamp. Noble gas based flash lamps are also described. The heating generally can be performed in a non-oxidizing atmosphere. Following the fusing of the silicon particles into a solid structure, additional processing steps can be performed to incorporate the resulting structure into the device.

### EXAMPLES

The Examples below demonstrate the formation and deposition of silicon inks. The ink samples were prepared from dispersions of crystalline silicon nanoparticles. The nanoparticles were initially prepared as powders using laser pyrolysis. The powders of silicon nanoparticles were formed essentially with the apparatus and methods as described in Example 2 of the '286 application cited above. The particles were collected in an enclosure to provide reasonable isolation from the ambient atmosphere. Doped and intrinsic (no dopant) silicon nanoparticles were synthesized and used as described in the following examples. Doped silicon particles comprised 2-4 atomic percent phosphorous (n++) or boron (p++). The nanoparticle powders comprised silicon nanoparticles with an average primary particle size of about 7 nm to about 30 nm. To simplify the discussion in the examples that follow, references to particle size will be understood to implicitly mean average primary particle diameter, unless indicated otherwise. For example, a dispersion formed from 7 nm nanoparticles will be understood to mean a dispersion formed from nanoparticles having an average primary particle diameter of about 7 nm.

### Example 1

This example demonstrates the effect of dispersion method and silicon nanoparticle property on ink formation. In particular, effect of sonication type, sonication sequence, particle concentration, particle size, and doping type were investigated. This example also demonstrates the formation of films from the resulting spin coating inks.

To demonstrate formation, 9 spin-coating inks were formed from dispersions of crystalline silicon nanoparticles synthesized as described above. For each sample, a shiny was formed with the same starting solid concentration by adding an appropriate amount of nanoparticle powder to a volume of isopropanol. The initial slurry was then subjected to initial mixing by bath sonication (samples 1-8) or probe sonication (sample 9) for a selected amount of time and at a selected temperature to form a dispersion. The bath sonicator and probe sonicator had powers of 300 W/37 kH and 150 W/20 kH, respectively. The actual operation condition of probe sonicator in this Example was 40% power with 50% pulse. Ink samples were well capped in containers for bath sonication whereas they were prepared in inert atmosphere like glovebox for probe sonication to minimize or avoid oxidation of Si. The resulting dispersion was then subjected to centrifugation to remove a portion of the sample, which may have included undispersed large particles, and foreign particles which contained metal impurities. Centrifugation was performed in two-steps. The dispersion was first centrifuged at 9500 rpm for 20 min. The supernatant was then decanted to another centrifuge tube and centrifuged at 9500 rpm for another 20 min. For samples 1-6 and 9, the supernatant of the second centrifugation was decanted into an ink container. For samples 7 and 8, the supernatant was bath sonicated for 3 hr.-6 hr. before being transferred to a storage container. The spin-coating inks thus formed had a silicon particle concentration of about 1-7 weight percent (“wt %”).

The inks were evaluated by spin coating them onto crystalline silicon wafer substrates to form a film. Prior to spin-coating, the wafer substrate was cleaned by placing it in a buffered oxide etch (“BOE”) for about 0.5 min. to about 1 min. The BOE solution comprised 34.86% ammonium fluoride and 6.6% hydrofluoric acid in water. The ink was then spin-coated onto the cleaned substrate in a glove-box environment substantially free from contaminating sources. The ink was spin-coated onto the substrate at 1000 rpm-1500 rpm for about 10 sec.-15 sec. The coated substrate was then dried by heating it at about 85° C. for about 5 minutes on a hotplate to remove solvent. The dried ink layers had an average thickness of about 1 μm. The thickness of the dried ink layer was measured using a profilometer (α-Step™ 300, KLA Tencore). In order to obtain thickness measurements, a given spin recipe was used to form a dried ink layer on a polished wafer substrate. A stylus in contact with the dried ink layer was then scanned horizontally over a distance of about 0.5 mm to about 1 mm on the dried ink layer and the vertical displacement of the stylus was recorded. A scribe was performed to create a step to facilitate the measurement with the stylus. An average thickness was obtained based on measurements of four individual spots on wafer surface (middle points between the edges of north, south, east, and west to center of the wafer). Sample and process parameters for the samples are displayed in Table 1.

TABLE 1

| | | | Post- | | Average |
|---|---|---|---|---|---|
| | Initial | | Centrifugation | | Primary |
| Sample | Mixing | Initial Mixing | Bath Sonication | Doping | Particle Size |
| No. | Sonication | Time, Temp | Time, Temp. | Type | (nm) |
| 1 | Bath | 3 hr., ambient | No | Intrinsic | 7 |
| 2 | Bath | 3 hr., ambient | No | n++ | 7 |
| 3 | Bath | 3 hr., ambient | No | p++ | 7 |
| 4 | Bath | 3 hr., ambient | No | Intrinsic | 30 |
| 5 | Bath | 3 hr., ambient | No | n++ | 20 |
| 6 | Bath | 3 hr., ambient | No | n+ | 25 |
| 7 | Bath | 10 min., ambient | 3 hr, ambient | Intrinsic | 7 |
| 8 | Bath | 3 hr., 4-10° C. | 6 hr., 4-10° C. | n++ | 7 |
| 9 | Probe | 20 min, ambient | No | n++ | 7 |

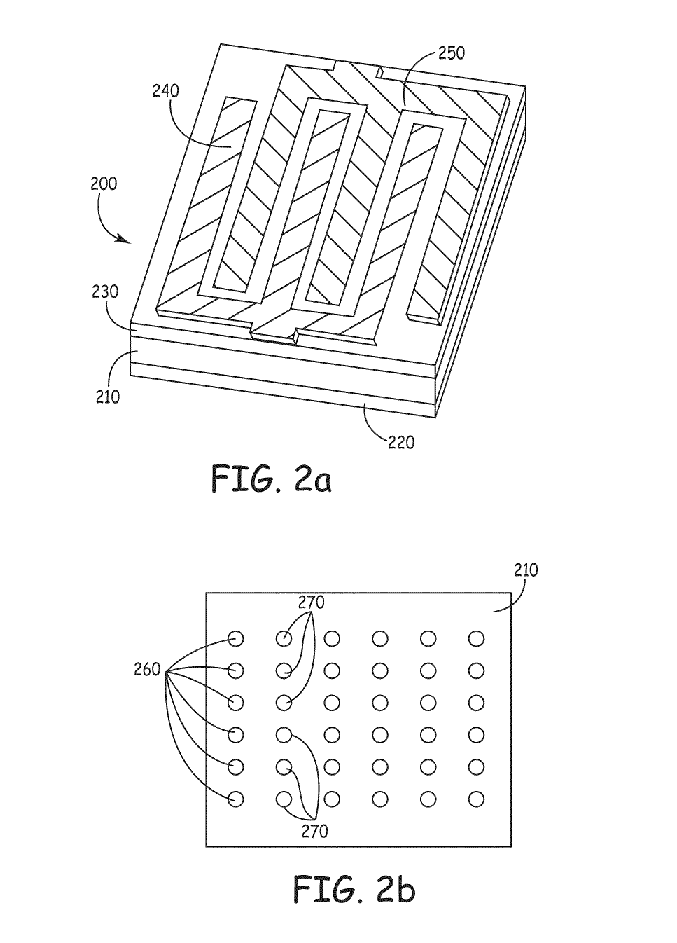

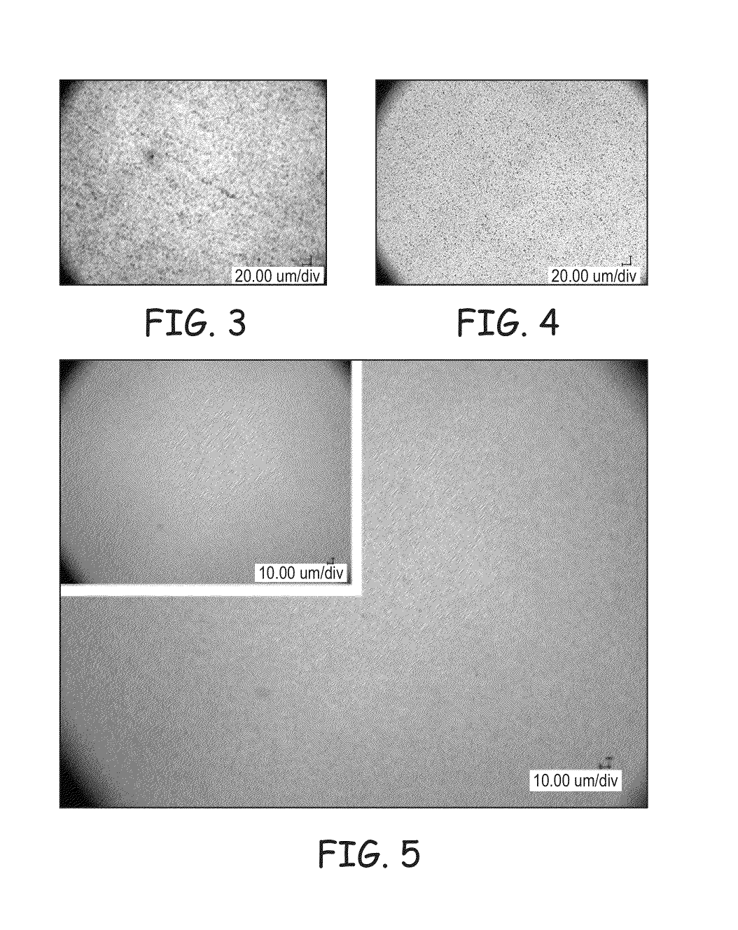

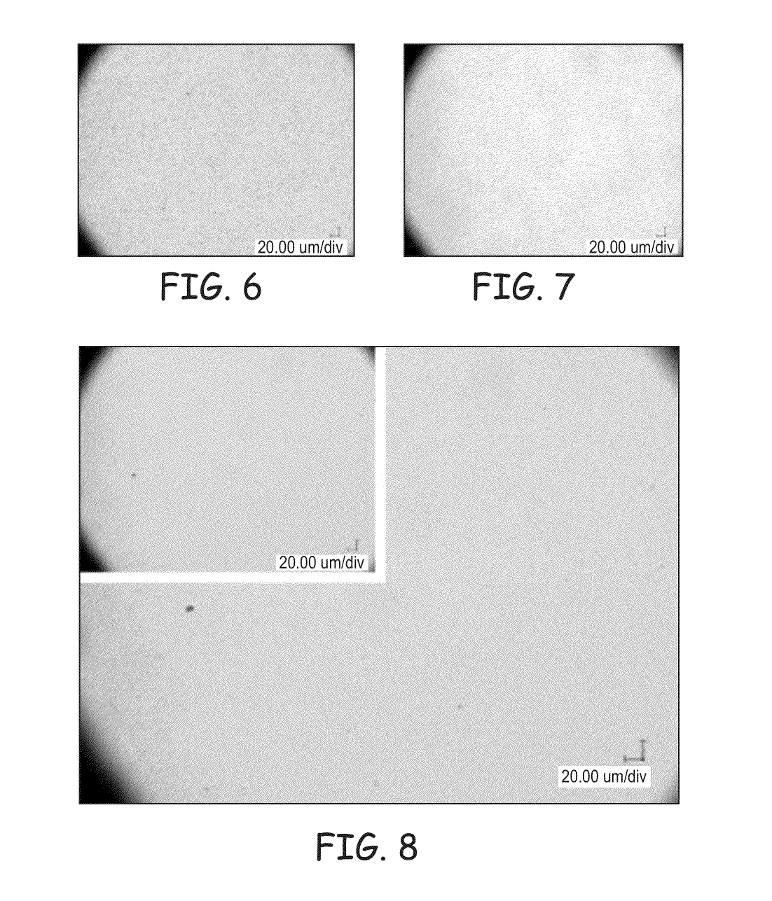

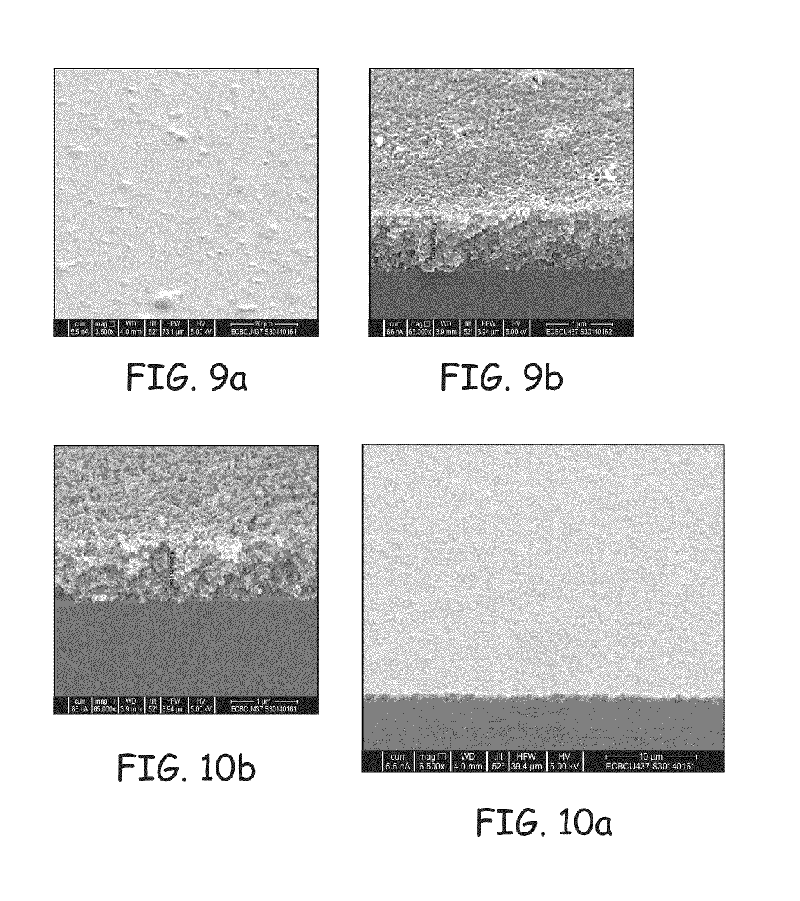

With respect to inks prepared from larger Si nanoparticles, films formed from 20 nm or larger nanoparticle inks had a lower defect density relative to films formed from 7 nm nanoparticle inks. Defect density was evaluated by visual observation of microscopy images to evaluate film defects such as pot marks. FIGS. 3-8 are optical microscopy images of the film coated surface of samples 1-6, respectively. Comparison of FIGS. 3 (sample 1) and 6 (sample 4) shows that the film of sample 1 (intrinsic, 7 nm) had a greater number of defects than sample 4 (intrinsic, 30 nm). The same trend can be seen from n++samples. Sample 5 (20 nm) had much lower defect density than sample 2 (7 nm) based on images of FIGS. 7 and 4, respectively. FIGS. 9a and 9b are scanning electron microscopy (“SEM”) images, taken at different magnifications, respectively showing a tilted top-view and a cross-section of sample 2 (7 nm). FIGS. 10a and 10b are SEM images, taken at different magnifications, showing tilted top-view and a cross-section of sample 5 (20 nm), respectively. The different levels of defect can be sensed based on variations of film thickness or surface roughness of the spin-coated films revealed by these images. Comparison of these two sets of images further confirms that the film of sample 5 had a more uniform thickness. Generally, larger size nanoparticle inks show better film quality. The size dependence of dispersion quality is possibly related to hard-agglomeration level of starting powder, particle surface property, and dispersion method. Furthermore, in terms of number of defects, samples 5 (n++, 20 nm), and 6 (n+, 25 mu) had less than 20 defects each from FIGS. 7 and 8. Interestingly, sample 3 (p++, 7 mu) also shows good film quality with less than 20 defects in FIG. 5. From this aspect, the defect level is also dependent on doping type.

With respect to inks prepared from nanoparticles with different doping types, the film formed from p++doped nanoparticles had a lower defect density than the analogous films formed from intrinsic and n++doped nanoparticles with similar particle sizes. Comparison of FIG. 5 with FIGS. 3 and 4 reveals sample 3 (p++, 7 mu) had a lower defect density than both sample 1 (intrinsic, 7 nm) and sample 2 (n++, 7 mu). The dispersion quality varies with doping type is likely due to dopant induced different surface properties of Si nanoparticles or hard-agglomeration levels during particle synthesis, or other dopant or dopant precursor related factors.

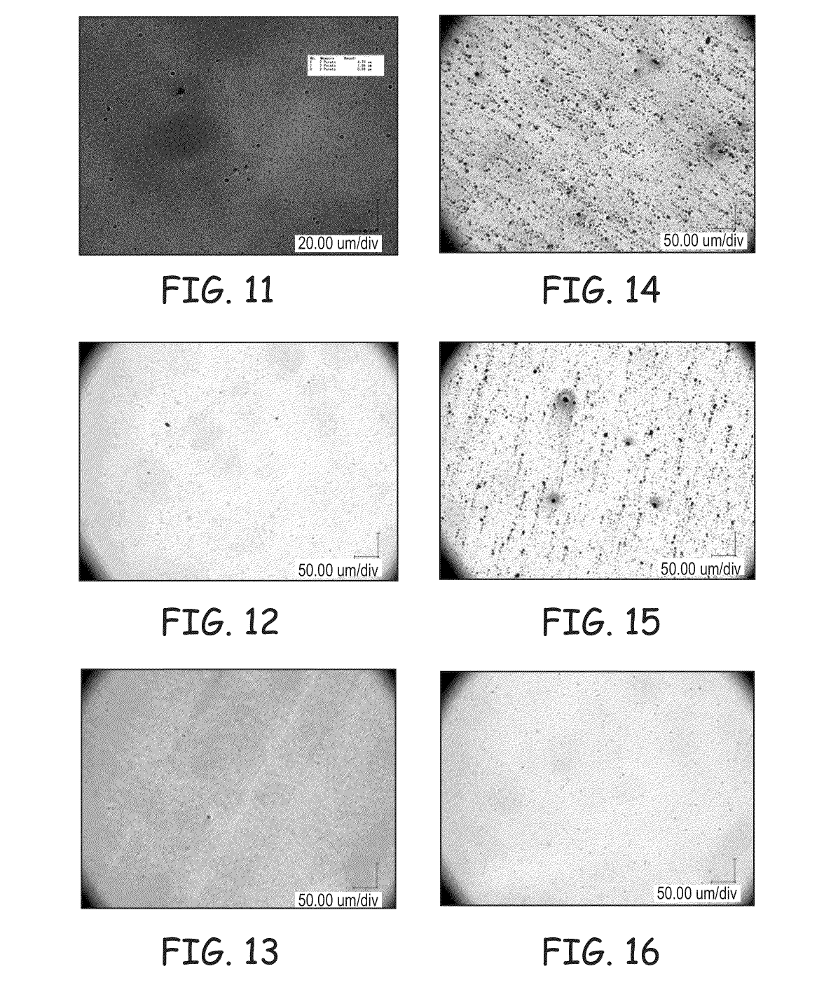

With respect to inks prepared with probe sonication, films formed from samples prepared with probe sonication had a lower defect density than those formed from samples with bath sonication. FIG. 11 is an optical microscopy image showing the film formed from ink sample 9. The FIGS. 11 and 4 demonstrate the film formed from the ink sample initially mixed with probe sonication (sample 9) had fewer defects than the film of sample initially mixed with bath sonication (sample 2). The results demonstrate that probe sonication is technically more efficient than bath sonciation even with lower power output due to less power loss or more power absorption by dispersion solutions although other issues such as scalability and metal contamination are associated with this method. However, the results indicate that besides bath sonication, more intensive de-agglomeration method(s) can be effectively implemented into current dispersion procedure to further improve dispersion quality. Moreover, number of de-agglomeration steps (e.g. bath sonication steps) is sometimes also a useful aspect to achieve better quality. It is further noted that samples 1-6 and 9 were not subjected to post-centrifugation sonication.

With respect to inks prepared with post-centrifugation sonication, films formed from certain samples prepared with post-centrifugation sonication had a lower defect density relative to films formed from samples without this extra step of sonication. FIGS. 12 and 13 are optical microscopy images showing the films formed from ink samples 7 and 8, respectively. Ink samples 7 and 8 were subjected post-centrifugation sonication. Ink samples 1 and 2, which were used to form the films shown in corresponding FIGS. 3 and 4, are similar to ink samples 7 and 8, respectively, but without post-centrifugation sonication. Comparison of FIGS. 12 and 13 with FIGS. 3 and 4, respectively, reveals that films formed from ink samples 7 and 8 had significantly reduced numbers of defects relative to the corresponding films formed from ink samples 1 and 2. These results demonstrate that post-centrifugation sonication of certain ink compositions can significantly enhance the quality of films formed from the resulting silicon inks. It is noted that the effectiveness of post-centrifugation sonication was concluded from specific samples (e.g. 7 nm, n++) and whether a similar phenomenon can occur for other types of Si nanoparticles is still under investigation.

Furthermore, it is known that dispersion quality can be altered by concentration variation and generally low concentration is relatively easier to achieve better dispersion. Silicon nanoparticle dispersion follows the general trend of particle dispersion that is lowering concentration can reduce frequency of particle-particle interaction to form larger secondary particles. Thus, with respect to Si concentration, films formed from lower concentration ink should have better quality.

### Example 2

This Example demonstrates the effects of formation parameters on the viscosity of spin-coating inks. In particular, this Example demonstrates the effects of initial mixing method, centrifugation parameters, and post-centrifugation sonication parameters on spin coating ink viscosity.

For this Example, 7 spin-coating inks were formed from dispersions of 7 nm, n++, doped silicon nanoparticles synthesized as described above. For each sample, a slurry was formed with the same initial solid concentration by adding an appropriate amount of nanoparticle powder to a volume of isopropanol. The slurry was then subjected to initial mixing to form a dispersion. For samples 1-4, 6 and 7, the slurry was initially mixed by bath sonication at ambient temperature for 3 hr. For sample 5, the slurry was initially mixed by centrifugal planetary mixing (THINKY USA, Inc.) at ambient temperature for 2 min. at 2,000 rpm. After initial mixing, the resulting mixtures were centrifuged to remove less well dispersed portion of the sample. Samples 1-5 were centrifuged at 9500 rpm for 40 min. Samples 6 and 7 were centrifuged using a two-step process with decanting between centrifuge steps, as described in Example 1. For sample 1, the supernatant was transferred to a sample container. For samples 2-7, the supernatant was subjected to post-centrifugation soniciation. In particular, sample 2 was bath sonicated for 1 hr. at ambient temperature. Samples 3-7 were bath sonicated for 3 hours at either ambient temperature (samples 3, 5 and 6) or at 4° C.-10° C. (samples 4 and 7). Samples 2-7 were then transferred to sample containers.

The ink dispersions were evaluated by viscosity measurement at 25° C. with a viscometer (DV-II+Pro, Brookfield) and other characterizations including particle concentration and particle dispersion size were also done for viscosity analysis. The final Si concentration in ink was measured by Thermogravimetric Analysis (“TGA”). The average secondary particle size was measured using dynamic light scattering (“DLS”). In particular, DLS measurements were performed on diluted ink samples, in order to increase the accuracy of the measurements. For a given ink, DLS measurements were performed on sample diluted to 0.1 wt % silicon particles and on a sample diluted to 0.01 wt % silicon particles. In addition, the ink samples were also evaluated as films, formed with spin coating similarly as described in Example 1 above, with following modifications to evaluate film quality based on different film thickness. In particular, each ink was spin coated onto two different silicon wafer substrates using different spin conditions to obtain two different film thicknesses. For relatively thick film, each ink was coated onto a first substrate by spin coating at 1,000 rpm for 10 sec. and subsequently at 1,500 rpm for another 10 sec. Likewise, for relatively thin film, the ink was coated onto a second substrate by spin coating at 4,000 rpm for 10 seconds and subsequently at 4,500 rpm for another 10 seconds. The coated substrates were then dried by heating at about 85° C. for about 5 minutes on a hotplate to remove solvent. Sample and process parameters are displayed in Tables 2 and 3, below. It is noted that based on optical images, the film quality did not vary significantly with the variation of film thickness. Thus, for simplification, the FIGS. 14-16 displayed in following discussion were images taken from the relatively thick films.

TABLE 2

| | | | Centri- | | |
|---|---|---|---|---|---|
| Sample | Initial Mixing | | fuge | Post-Centrifugation Mixing | |
| No. | Type | Parameters | Steps | Type | Parameters |
| 1 | Bath Sonication | 3 hr., ambient | 1 | No | No |
| 2 | Bath Sonication | 3 hr., ambient | 1 | Bath Sonication | 1 hr., ambient |
| 3 | Bath Sonication | 3 hr., ambient | 1 | Bath Sonication | 3 hr., ambient |
| 4 | Bath Sonication | 3 hr., ambient | 1 | Bath Sonication | 3 hr., 4-10° C. |
| 5 | Centrifugal | 2 min. at | 1 | Bath Sonication | 3 hr., ambient |
| | Planetary Mixing | 2,000 rpm | | | |
| 6 | Bath Sonication | 3 hr., ambient | 2 | Bath Sonication | 3 hr., ambient |
| 7 | Bath Sonication | 3 hr., ambient | 2 | Bath Sonication | 3 hr., 4-10° C. |

TABLE 3

| | | | | | Film Thickness | |
|---|---|---|---|---|---|---|
| | | | | | (nm) ± 50 nm | |
| | TGA | Average Secondary | | | After spin- | After spin- |
| Sam- | Final | Particle Size | | Vis- | coating at | coating at |
| ple | Solid | (nm), PDI | | cosity | 1 krpm/ | 4 krpm/ |
| No. | (wt %) | 0.1 wt % | 0.01 wt % | (cP) | 1.5 krpm | 4.5 krpm |
| 1 | 5.4 | 104.5, 0.23 | 108.4, 0.26 | 24 | 930 | 350 |
| 2 | — | 96.5, 0.25 | 97.0, 0.26 | 24 | 727 | 316 |
| 3 | 5.4 | 92.4, 0.23 | 96.8, 0.24 | 31 | 980 | 318 |
| 4 | — | 96.5, 0.28 | 91.9, 0.28 | 38 | 1050 | 452 |
| 5 | 0.3 | 84.3, 0.22 | 86.1, 0.21 | 2.4 | 68 | 40 |
| 6 | 4.9 | 98.5, 0.27 | 95.9, 0.23 | 8.2 | 687 | 280 |
| 7 | 4.9 | 93.8, 0.27 | 92.5, 0.25 | 14.2 | 582 | 330 |

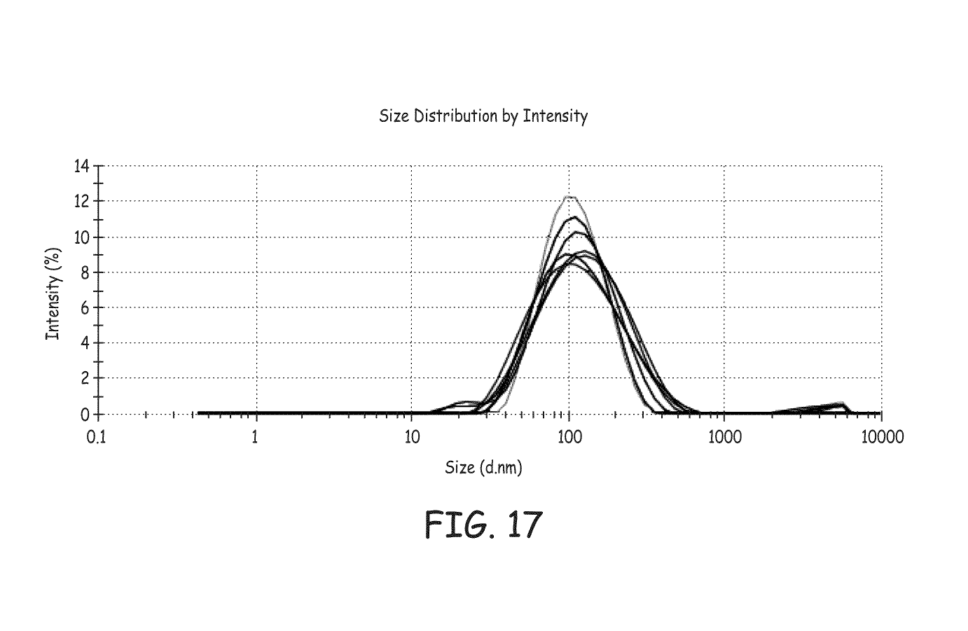

The ink samples prepared with various ink formation methods had different viscosity although the average secondary particle size of the silicon particles in the ink samples was not substantially varied. Table 3 displays the average secondary particle size of silicon particles in inks 1-7. The average secondary particle sizes were calculated from secondary particle size distributions obtained by DLS measurements on ink samples diluted to 0.1 wt % and 0.01 wt % silicon particles. Table 3 demonstrates that regardless of the particular formation protocol used to form the inks, the average secondary particle size of the silicon particles in inks 1-7 was similar. Furthermore, the small variation in the polydispersity index (“PDI”) over all samples suggests that the width of the secondary particle size distribution was also not significantly affected by the ink formation method. FIG. 17 is a graph containing plots of the secondary particle size distributions (i.e. intensity versus secondary particle size) of diluted samples of inks 1-7 having 0.1 wt % silicon particles. FIG. 17 demonstrates that variation in the formation protocol did not significantly affect the average secondary particle size of silicon particles in inks 1-7. It follows from these results that same average secondary-particle size does not necessarily mean that the same viscosity was achieved. On other hand, the viscosity variation with different preparation methods is also sensitive to other factors such as particle loading and particle/particle interaction under shearing stress. For instance, TGA data shows that sample 3 with the highest Si concentration had the highest viscosity of 38 cP whereas sample 5 with the lowest Si concentration had the lowest viscosity of 2.4 cP.

The ink sample initially homogenized with centrifugal planetary mixing had the lowest viscosity as well as particle concentration, relative to the other ink samples in this Example. These results relate to a greater amount of material separated from the samples during the centrifugation of the samples that were not sonicated prior to centrifugation. Referring to Table 3, ink sample 5 had the smallest viscosity (2.4 cP) and formed the thinnest film after spin-coating, relative to the other ink samples. These results suggest that centrifugal planetary mixing under the conditions used to obtain these results was not as effective as bath sonication at forming a good dispersion of the particles.

The ink samples prepared with a two-step centrifugation process had lower viscosities but formed films with greater uniformity. Table 3 reveals that the viscosities of samples 6 and 7, both formed using a two-step centrifugation process, were 8.2 cP and 14.2 cP, respectively, lower than the viscosities of samples 1-4 (prepared with a one step centrifugation process). This trend is especially evident for these two sets of comparisons: (sample 6 and sample 3) and (sample 7 and sample 4). The lower viscosity is likely associated with both lower Si concentration and less large agglomeration relative to one-step centrifuged samples. Furthermore, the thickness of the film formed from samples 6 and 7 was thinner than the films of samples 1-4 and thicker than sample 5. The film thickness data are in good agreement with TGA Si concentration data, confirming lower concentration results thinner film thickness. Optical microscopy images of dried spin coating films formed from samples 1-7 were taken. The representative images are displayed in FIGS. 14-16, which are optical microscopy images of the films formed from samples 1, 2 and 6, respectively. FIG. 15 is representative of the films formed from samples 2-4 and FIG. 16 is representative of the films formed from samples 6 and 7. Referring to the figures, the films of samples 6 and 7 (both two-step centrifugation) had the least amount of visible defects in the dried coatings. In addition, comparison of FIG. 15 (samples 2-4) and FIG. 14 (sample 1) also confirms the benefit of post-centrifugation sonication on film quality improvement as demonstrated in Example 1, although the quality of samples 2-4 was compromised by one-step centrifugation. Furthermore, the difference of ink preparation between sample 2 (FIG. 4) from Example 1 and sample 1 (FIG. 14) from this Example is just the centrifugation steps with the first and the latter ones having two-step and one-step centrifugation steps, respectively. Comparison of these two figures, it is evident that sample 2 from Example 1 has improved film quality. The merit of two-step centrifugation is partly attributed to the reduction of contamination of large particles to dispersion solution. During initial particle/solvent mixing procedure, more or less, some particles can stick onto inner wall of container, which is either non-wetted area or wetted area but not immersed into solvent. The amount of these particles is not necessarily human-eye detectable but they were actually there. These non-dispersed particles have tendency to contaminate the supernatant during decanting process. Thus, the second step of centrifugation is capable of centrifuging out the large particles introduced from the first decanting process after the first centrifugation. It is thus possible that the higher viscosity and higher solid concentration of one-step centrifuged samples were caused by these large particle clusters.

Interestingly, it is noted that the ink sonicated with lower temperature had higher viscosity. The viscosity data comparisons in Table 3 for two sets of samples: (sample 4 and sample 3) and (sample 7 and sample 6) demonstrate that applying lower temperature sonication lead to higher viscosity although corresponding film thickness was not significantly different. Moreover, the spin coating films were also not significantly improved with lower sonication temperature. The cause for above results is not clear yet.

### Example 3

### Formation and Printing Properties of Screen Printing Pastes

This Example demonstrates the screen printing performance of screen printing pastes that are formed with a sonication step after centrifugation and with a formulation of only solvents and Si nanoparticles. As with the formation of spin-coating inks, described in Example 1 above, the samples in this Example were prepared using the same basic formation steps of (1) initial mixing, (2) centrifugation, and (3) post-centrifugation sonication. However, desirable screen printing pastes are, in general, more viscous than corresponding spin-coating inks. Therefore, the formation of paste samples in this Example further involved concentrating the dispersion and creating a solvent blend. The steps of concentrating the dispersion and solvent blend creation were performed between the centrifugation and post-centrifugation sonication steps, and after the post-centrifugation sonication, as described below.

For this Example, 2 paste samples were prepared from n++, doped crystalline silicon particles having an average primary particle size of 20 nm, synthesized as described above. For each paste sample, a slurry was formed by adding an appropriate amount of nanoparticle powder to a volume of isopropyl alcohol (“IPA”). The mixture was then initially mixed by bath sonication for 3 hr. at ambient temperature to form a dispersion. The dispersion was then centrifuged at 9500 rpm for 20 minutes to remove more poorly dispersed components of the dispersion. The supernatant was then decanted to another centrifuge tube and centrifuged at 9500 rpm for another 20 min. The supernatant of the second centrifugation was then decanted and placed in a rotovap for 30 min at 137 mbar, to partially remove IPA and concentrate the dispersion to some extent. Subsequently, a volume of propylene glycol (“PG”) was added to the concentrated dispersion and the resulting mixture was subjected to post-centrifugation sonication for 3 hr. at ambient temperature. The sonicated mixture was then placed in the rotavapor again to further remove IPA to the maximum amount. After this step, for paste sample 1, the rotavapored mixture was then transferred to a sample container. For paste sample 2, the rotavapored mixture was further mixed in a centrifugal planetary mixer at 2,000 rpm for 6 minutes, before being transferred to a sample container. The purpose for this type of mixing was to further increase the homogeneity of the paste. The final paste samples comprised 10 wt %-14 wt % silicon particles, majority of PG, and some residue of IPA.

### Screen-Printing Performance

To demonstrate screen printing performance of the paste made with only solvents and Si nanoparticles, the paste samples were subjected to manual screen printing onto crystalline silicon wafers. Specifically, a manual screen printer and/or an HMI semi automatic screen printer were used for the screen printing trials. Trampoline mounted screens from Sefar Inc. with long elongation polyester mesh were used. The typical mesh count was 380 threads per inch with mesh opening 36 μm, thread diameter 27 μm, open area 42% and mesh thickness 55 μm. 5 μm thick MM-B emulsion from Sefar Inc. that is capable of ultra-fine resolution and crisp edge definition was used. This emulsion has good resolution potential and a superior resistance to chemical solvents and abrasive pastes. To screen print, a screen was first prepared by depositing an appropriate volume of paste onto one end of a screen. For each screen print cycle, the screen was then suspended a short distance above a new wafer substrate and the screen was flooded by placing ink on the screen. After flooding, the paste was printed by pulling a squeegee across the screen. Between each print cycle, the paste allowed to rest on the screen for about 1 min for continuous manual printing mode. The screens were masked to have dot and/or line patterns. After printing, all the samples were subsequently heated at 200° C. for 5 min. in Air on a hotplate to remove most of solvents.

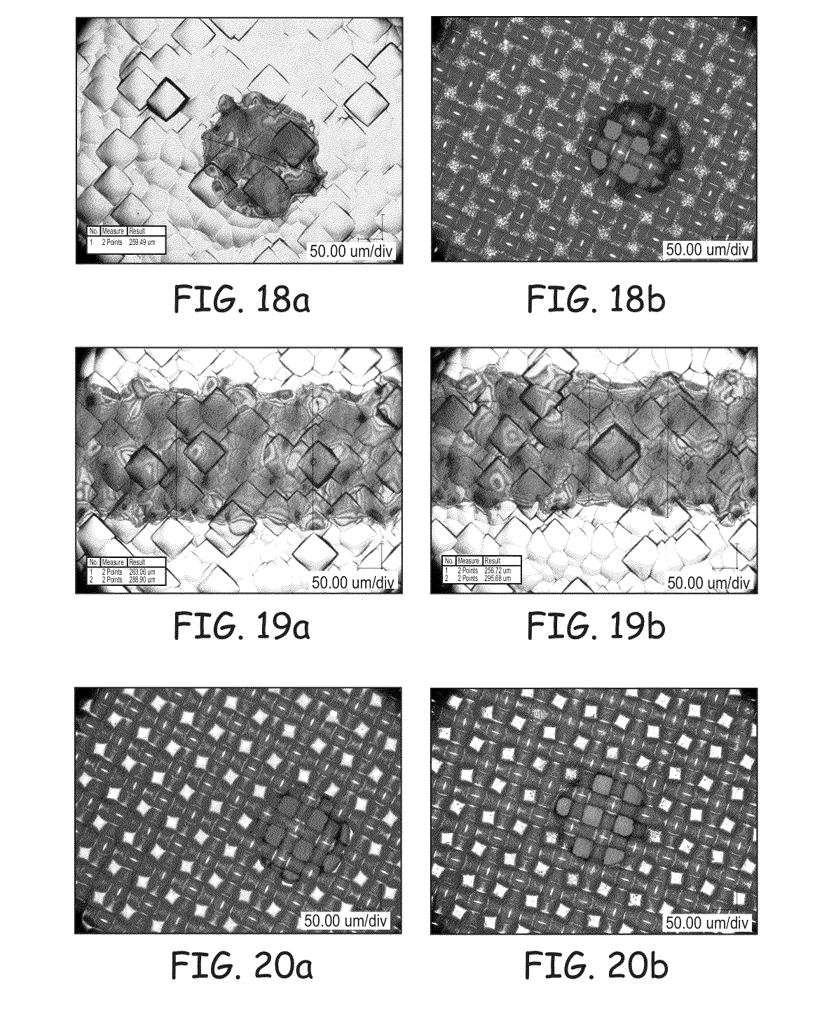

The quality of prints was deteriorated with increase of screen print cycles. FIG. 18a is an optical microscopy image of 200 μm dot, printed from the 5^{th} cycle with paste sample 1. An optical image was also taken after the 2 hours of print cycles (data not shown). The optical microscopy images demonstrated that over increasing print cycles, dots printed with paste sample 1 had appreciable decrease on print quality due to screen clogging or other issues related to screen flooding and paste rheology. FIG. 18b is an optical microscopy image of the screen used to print the dots that was taken after 2 hours of continuous dot printing. It shows screen clogging was present. An optical microscopy image of a screen used to continuously print a line showed a similar amount of clogging to that observed in FIG. 18b after 2 hours on the screen. Nevertheless, the paste made with above method only works for certain amount of short printing cycles without noticeable screen clogging.

The paste prepared with a final centrifugal planetary mixing had similar printing characteristics to the paste prepared without centrifugal planetary mixing. FIGS. 19a and 19b are optical microscopy images of lines screen printed with paste samples 1 and 2, respectively. The images in FIG. 19 were taken after the 10^{th} prints. Referring to the figures, the spreading and thickness of the line printed with paste sample 1 (no centrifugal planetary mixing) was similar to that of the line printed with paste sample 2 (centrifugal planetary mixing). FIGS. 20a and 20b are optical microscopy images of screens after 1 hour of continuous screen printing of dots with samples 1 and 2, respectively. The figures reveal slight clogging at the edges of the screen feature for both screens, although clogging was less apparent for screen used to print sample 1. Optical microscopy images of screens used to continuously print lines with samples 1 and 2 revealed clogging very similar to that observed in FIGS. 20a and 20b after 1 hour of print cycles. The above results indicate that good dispersion and mixing is only one of the factors leading to screen-printable Si paste and no significant improvement of paste quality is expected without optimization of other properties especially rheology and chemistry of paste. To improve the printability and printing quality of above Si paste (solvent only based), use of additives for paste modification is one of the choices.

### Example 4

### Pastes with Polymer Additives

This example demonstrates the effects of polymer additives on the performance of screen printing pastes. In particular, the effect of using ethyl cellulose (“EC”) as a polymer additive is studied.

For this Example, 7 paste samples were prepared as shown in Table 4. Sample 1 was the same as the sample 1 in Example 3 and it was PG based without EC. The rest of 6 samples were prepared based on the method for sample 1 but with extra steps for EC addition. The extra steps include a step for dissolving EC into Terpineol and a step for mixing EC solution with a base paste (same as sample 1) by THINKY mixer to form final paste. The samples were prepared with 20 nm, n++, doped crystalline silicon nanoparticles. Except sample 1, which had silicon nanoparticle concentration “[SiNP]” of 10-14 wt %, the samples 2 to 7 had [SiNP] and EC concentration “[EC]” concentrations varying from 3-6 wt % and 0-6.7 wt %, respectively. The paste samples were used to manually screen print lines and dots on a silicon wafer substrate using method as described in Example 3. After printing, the printed features were cured by heating the printed wafer substrates at a low temperature of 200° C. for 5 min. in Air on a hotplate. To further remove polymer additives, escalated temperatures were necessary. Unless specified, images of printed films were taken from the samples treated with the low temperature.

TABLE 4

| | Sample No. | | | | | | |
|---|---|---|---|---|---|---|---|
| | 1 | 2 | 3 | 4 | 5 | 6 | 7 |
| [EC] (wt %) | 0 | 4.7 | 6.7 | 0.85 | 2.5 | 0.65 | 3.3 |

### Printing Characteristics—Effect of Polymer Additive

In this study, samples 1 and 4 from Table 4 were characterized to demonstrate the improvement of printability of paste and quality of printed features due to the additive.

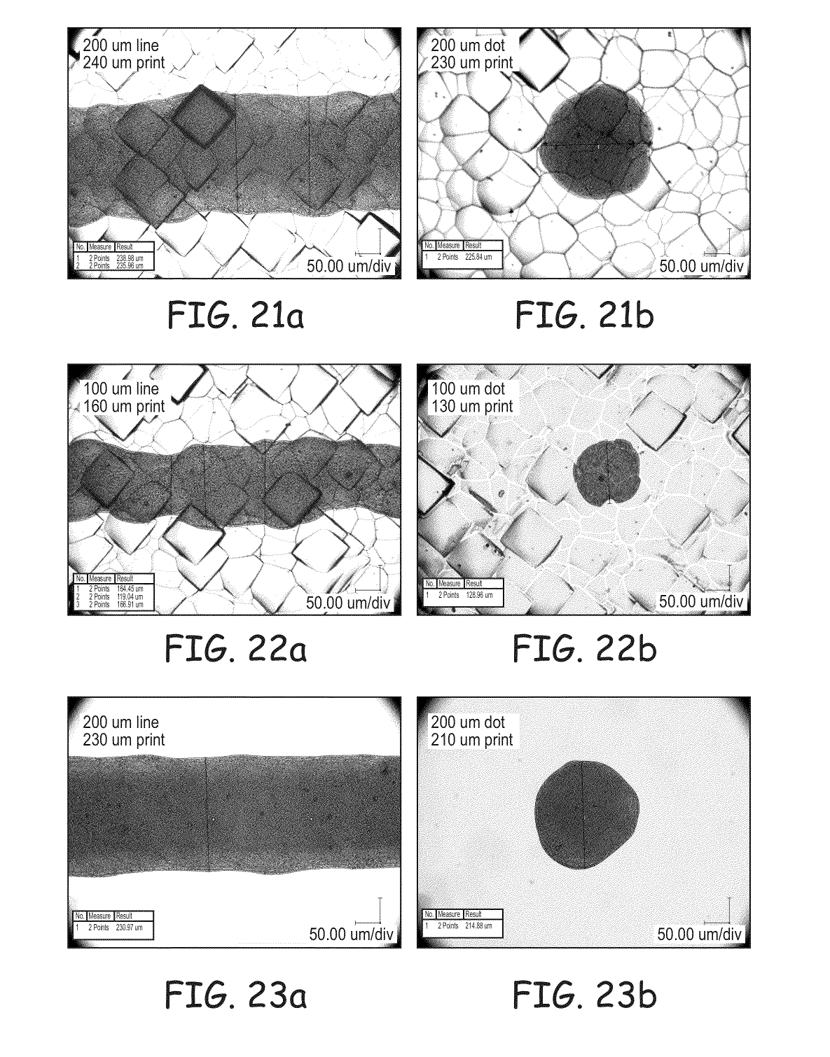

The sample prepared with polymer additive had improved edge definition relative to the sample prepared without polymer additive. FIG. 21 series are optical microscopy images showing a line (21a) and a dot (21b) printed on a silicon wafer during the 10^{th} print cycle with paste sample 4. The line and dot were printed with a width/diameter of about 200 μm. Comparison of FIG. 21a (sample 4) and FIG. 19a (sample 1 in Example 3) shows the sample with EC additive has improved printing quality with better edge definition, less spreading, and more uniformity. However, FIGS. 21a and 21b reveal some level of spreading after printing was still present. In particular, the line width and dot diameter spread by up to 20% and 15%, respectively. The existence of some spreading is likely due to low viscosity at high shear rate or insufficiency of EC content. Furthermore, it is noticed that smaller printed patterns and rougher substrate surface are generally easier to cause a relatively larger degree of post-print spreading. FIG. 22 series are analogous to FIG. 21 series but show a line (22a) and a dot (22b) printed with a width/diameter of 100 μm. These figures reveal that for these smaller patterns, the line width and dot diameter spread by up to 60% and 30%, respective, suggesting a relatively larger degree of post-print spreading with smaller printed structures. FIG. 23 series are analogous to FIG. 21 series showing lines (23a) and dots (23b) printed on polished silicon wafer during the 10^{th} print cycle. Comparison of these figures, demonstrates that screen printing on a polished wafer substrate slightly reduced the degree of post-print spreading with 15% (line) and 5% (dot) spreading. In general, it was observed that the spreading is usually more evident in larger facet areas on textured wafers. Above analysis suggests that adjusting paste rheology and chemistry by increase of EC/terpineol solution in Si paste can further improve quality of printed features.

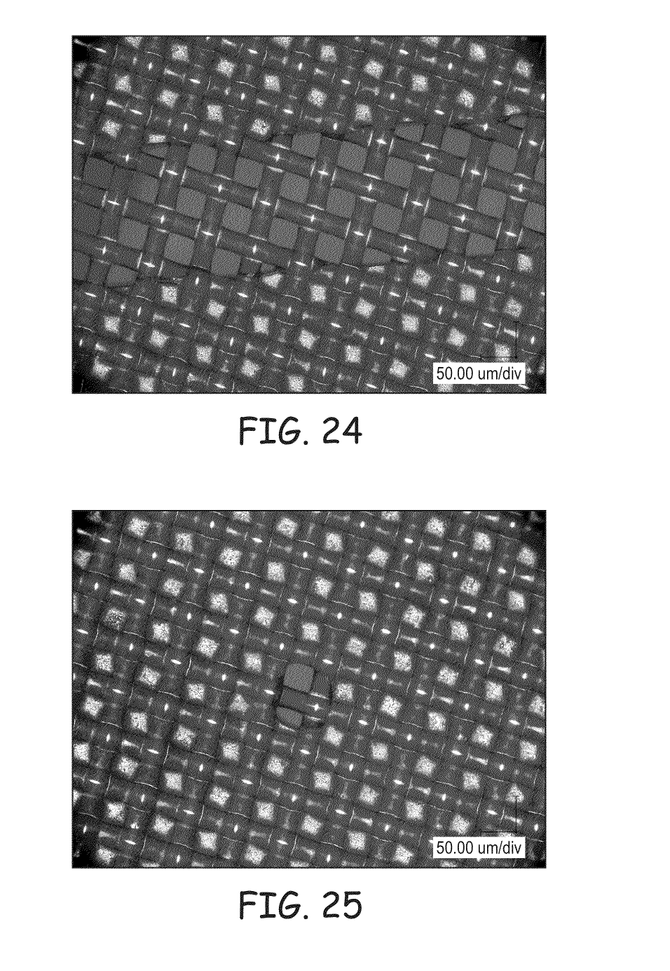

The sample prepared with a polymer additive had significantly reduced screen clogging relative to the sample prepared without polymer additive. FIGS. 24 and 25 are optical microscopy images of the screens used to print, respectively, a 200 μm line and 100 μm dot with paste sample 4, obtained after 2 hours of continuous printing. FIG. 18b from Example 3 is an analogous optical microscopy image of a screen used to print a dot with paste sample 1. The figures reveal that the screen used print sample 1 had noticeable clogging around the edges of the screen pores and, in the case of dot prints, almost total occlusion of some of the pores. Furthermore, the figures demonstrate the screens used to print paste sample 4 (prepared with additive of EC polymer in terpineol) had only minimal clogging near the edges of the pores and significantly reduced clogging relative to the screens used print paste sample 1. In addition, FIG. 25 from above comparison is 100 μm dot, which only had very minor clogging, suggesting the larger dots such as 200 μm should be no clogging as well because smaller screen openings more easily get clogged than the larger ones. It is further noted that the reduction of clogging is not necessarily only related to polymer additive (e.g. EC), but also related to solvent system (e.g. terpineol) and entire paste system.

### Paste Rheology

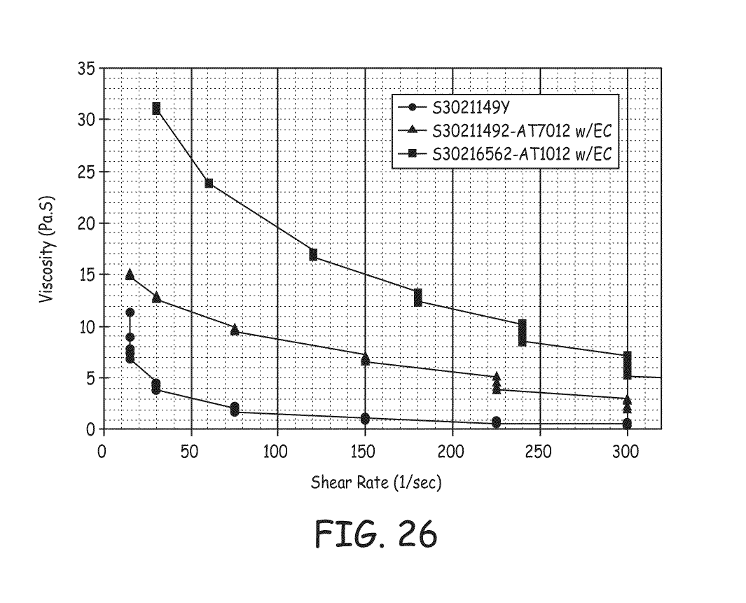

To demonstrate the rheology of screen printing pastes, 3 paste samples (samples 1, 2, 3) were used from Table 4. A rheometer (RS/-CPS, Brookfiled) was used to apply different shear rates to the paste samples and the corresponding viscosities were measured. FIG. 26 is a graph containing plots of shear rate versus viscosity for the different samples at different shear rates. The figure demonstrates that paste samples formed with EC (samples 2 and 3) had greater viscosities over the range of tested shear rates and, therefore, is consistent with above printing data, suggesting that EC can be a particularly beneficial component of inks formed for use in screen printing. The figure also demonstrates that sample 3 had a larger viscosity than sample 2 over the tested range of shear rates and demonstrates increase of EC concentration can further increases Si paste viscosity.

### Printing Characteristics—Concentration EC and Nanoparticle Concentrations

To demonstrate the effect of different concentrations of the ink components, specifically, concentration of ethyl cellulose [EC] and ratio of Si nanoparticles to EC concentration “[SiNP]/[EC]”, samples 4, 5, 6, and 7 from Table 4 were chosen for analysis.

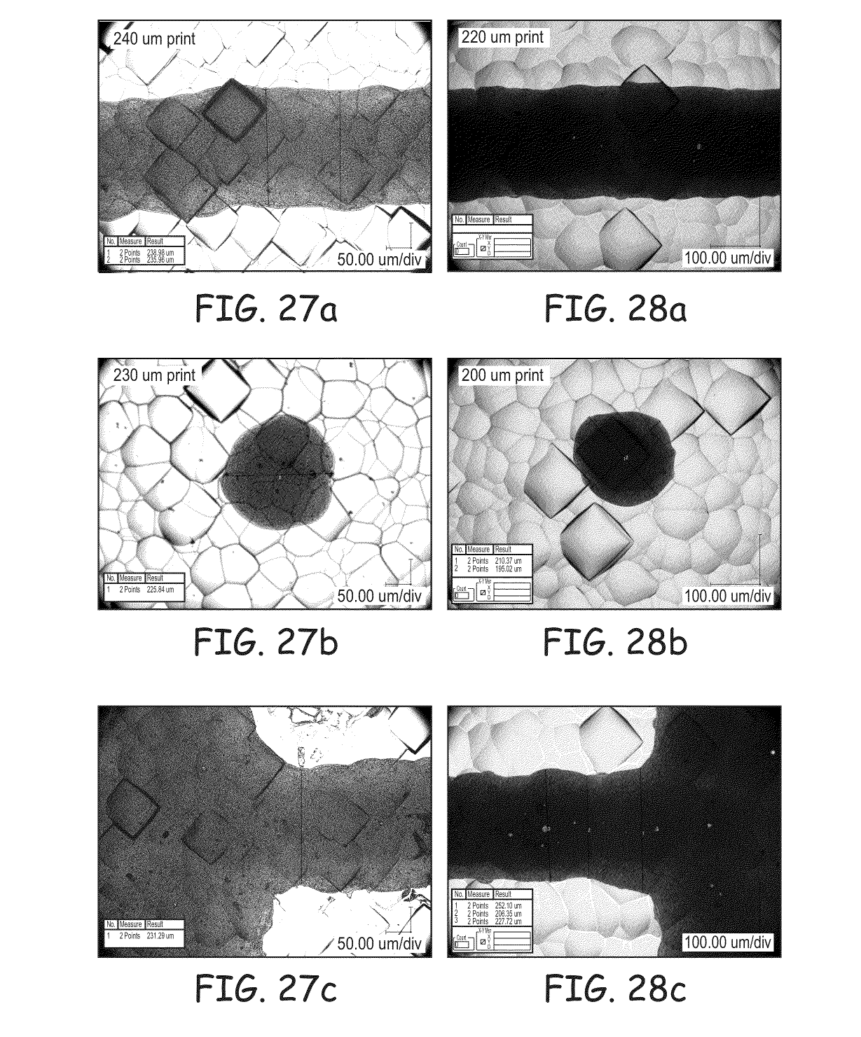

The effect of EC concentration is demonstrated in FIGS. 27-28 series. The ink samples were used to print lines and dots with corresponding widths and diameters of 200 μm on silicon wafer substrates, as described above. FIGS. 27a and 28a are optical microscopy images showing top-views of lines printed during the 10^{th} print cycle with ink samples 4 and 5, respectively. The figure demonstrates that increased EC concentrations can reduce post-print spreading and improve feature definition. In particular, these figures reveal that the line printed with sample 4 (0.85 wt % EC) spread to about 240 μm while the line printed with sample 5 (2.5 wt % EC) spread to only about 220 μm after printing. FIGS. 27b, 28b) and (27c, 28c) are analogous to FIGS. 27a, 28a) and show dots (FIGS. 27b and 28b) and irregular patterns (FIGS. 27c and 28c) printed with ink samples 4 (FIG. 27 series) and 5 (FIG. 28 series). These figures similarly show less post-print spreading of features printed with ink sample 5, relative to ink sample 4.

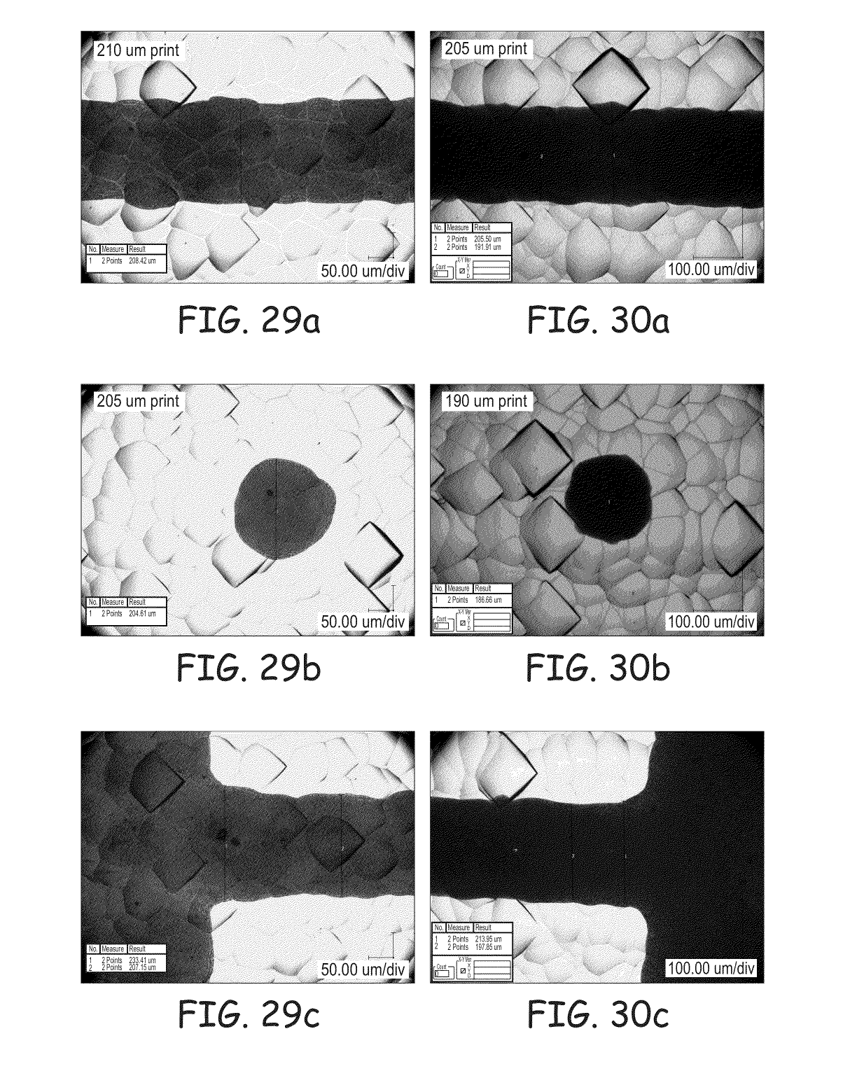

The effect of different [SiNP]/[EC] values at lower EC concentration is demonstrated in FIGS. 29a-29c. With respect to samples 4-7, [SiNP]/[EC] varied from lowest to highest as: sample 7<sample 5<sample 4<sample 6. FIG. 29a is an optical microscopy image showing top-view of line printed during the 10^{th} print cycle with ink sample 6. Comparison of FIG. 29a (sample 6) with FIG. 27a (sample 4) demonstrates that at lower EC concentrations, less post-print spreading was achieved by increasing [SiNP]/[EC]. In particular, the figures demonstrates that lines printed with sample 4 spread to about 240 μm while the line printed with sample 6 spread to only about 210 μm. FIGS. 29b and 29c are analogous to FIG. 29a and show a dot (FIG. 29b) and an irregular pattern (FIG. 29c) printed with ink sample 6. Comparison of these figures with FIGS. 27b and 27c similarly show less post-print spreading of features printed with ink sample 6, relative to ink sample 4. It is noted that the increase of [SiNP]/[EC] was mainly done by increase of Si loading. To what extent Si loading can be increased at such low range of [EC] without compromising the printability and printing quality can be further studied.

The effects of different [SiNP]/[EC] values at higher EC concentration is demonstrated in FIGS. 30a-30c. FIG. 30a is an optical microscopy image showing a top-view of a line printed during the 10^{th} print cycle with ink sample 7. Comparison of this figure to FIG. 28a (sample 5) demonstrates that at higher EC concentrations, less post-print spreading was achieved by decreasing [SiNP]/[EC], in contrast to what was observed at lower EC concentrations. In particular, the figures demonstrate that lines printed with sample 7 spread to only 205 μm while the line printed with sample 5 spread to about 220 μm. FIGS. 30b and 30c are analogous to FIG. 30a and show a dot (FIG. 30b) and an irregular pattern (FIG. 30c) printed with ink sample 7. These figures similarly show less post-print spreading of features printed with ink sample 7, relative to ink sample 5. Furthermore, it is noted that the decrease of [SiNP]/[EC] was achieved mainly by increase of EC content. To what extent EC can be increased until the printability and printing quality reach saturation platform is worth of continuous investigation.

### Ink Curing

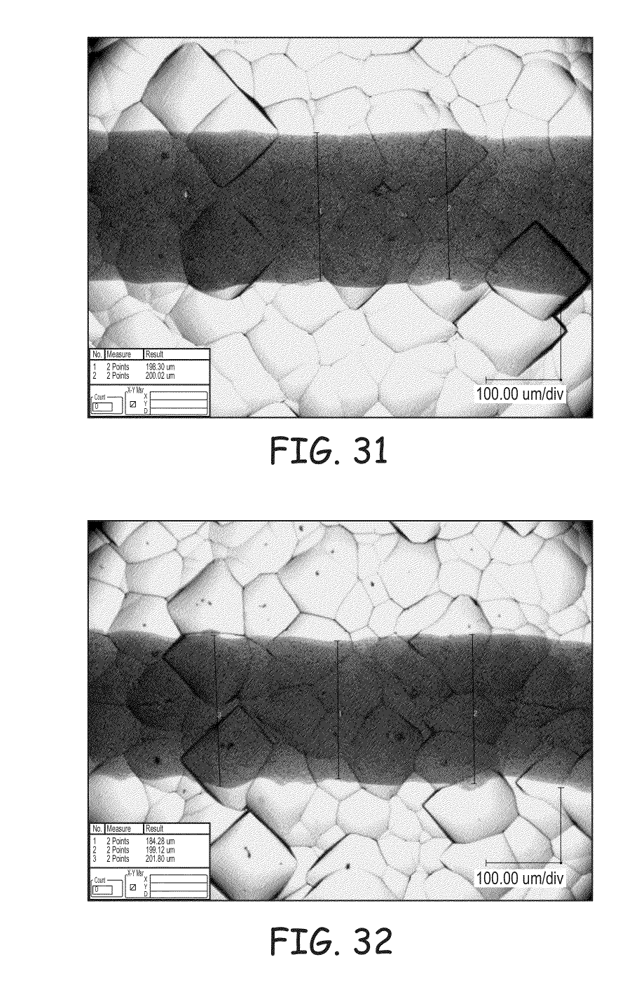

The effect of different curing conditions on layer formation was tested by subjecting 3 different printed substrates to different curing conditions. In particular, for each substrate, ink sample 7 from Table 4 was used to manually print a 200 μm wide line. Printed substrates 1-3 were cured under air at 200° C. for 5 min., under air at 400° C.-500° C. for no more than 15 min., and under nitrogen at 500° C. for 30 min, respectively. FIGS. 30a, 31, 32 are optical microscopy images showing top-views of printed substrates 1-3. Comparison of the figures reveals that relative to curing at 200° C., higher temperature treatment shows film integrity can be maintained without cracks and pinholes, film thickness is reduced or porosity is increased indicated by lighter color of films due to EC thermal decomposition, and feature definition can be kept with printed line widths on substrates 1-3 of 205 μm, 200 μm, and 200 μm, respectively. Overall, these results demonstrate that printed-film quality had no thermal degradation in terms of edge definition and film integrity.

### Example 5

### Impurities in Screen Printing Pastes

This example demonstrates the range and quantities of impurities in screen printing pastes.

To test the range and quantity of impurities, 2 screen printing pastes were formed from 20 nm, n++, doped silicon nanoparticles similarly as described in Example 3. Both paste samples were formulated to have a silicon nanoparticle concentration of about 10 weight percent. In preparing sample 2, additional efforts were made to further reduce the introduction of contaminants from the process equipment, particle synthesis, sample handling, and ink/paste formation. The composition and corresponding amount of impurities in the paste were measured using inductively coupled plasma mass spectrometry (ICP-MS) for both pastes. The results of the ICP-MS analysis are displayed in Table 5.

TABLE 5

| | Detection | Concentration | Concentration |
|---|---|---|---|
| | Limits | in Sample 1 | in Sample 2 |
| Elements | (ppb) | (ppb by wt) | (ppb by wt) |
| Aluminum | 0.5 | 12 | 3 |
| Calcium | 1 | 110 | 67 |
| Chromium | 0.5 | 8.5 | 0.9 |
| Copper | 0.5 | 3.3 | 1.6 |
| Iron | 1 | 140 | 45 |
| Lead | 0.5 | <0.5 | <0.5 |
| Magnesium | 0.5 | 14 | 6.6 |
| Molybdenum | 0.5 | <0.5 | <0.5 |
| Nickel | 0.5 | 5.5 | 0.6 |
| Potassium | 1 | 61 | 28 |
| Sodium | 1 | 750 | 60 |
| Titanium | 0.5 | 4.1 | 6.9 |
| Zinc | 0.5 | 12 | 70 |

The samples exhibited very low contaminant levels, especially with respect to transition metal contaminants. Overall the second sample had lower transition metal contamination, especially for Al, Cr, Cu, Fe, Ni and Na, although zinc contamination was somewhat higher in the second sample.

### Example 6

### Oxide Modified Screen Printing Pastes

This Example demonstrates formation and printing properties of a screen printing paste comprising silicon nanoparticles and silicon dioxide nanoparticles. The paste in this Example was prepared using the formation steps of (1) initial mixing, (2) centrifugation, (3) second mixing and (4) planetary mixing.

To demonstrate formation, an ink paste was formulated from n++doped crystalline Si nanoparticles and non-doped SiO₂ nanoparticles. The Si nanoparticles were synthesized as described above and had an average primary particle diameter of about 7 nm. The SiO₂ nanoparticles were synthesized as described in published U.S. Pat. No. 7,892,872 to Hieslmair et al., entitled “Silicon/Germanium Oxide Particle Inks, Inkjet Printing and Processes For Doping Semiconductor Substrates,” incorporated herein by reference, and had an average primary particle diameter of about 10 nm. Initially, a mixture was formed by adding 0.5 g of the Si nanoparticles to 9.5 g of ethylene glycol. The mixture was then bath sonicated for 3 hr. at room temperature to form a dispersion. The dispersion was subsequently centrifuged for 20 min. at 9,500 rpm. The supernatant was decanted and centrifuged a second time for 20 min. at 9,500 rpm. The supernatant of the second centrifugation was decanted and 0.2 g of the SiO₂ nanoparticles was added to supernatant to form a second mixture. The second mixture was then mixed in a centrifugal planetary mixture for 2 min. at 2,000 rpm to form the paste.

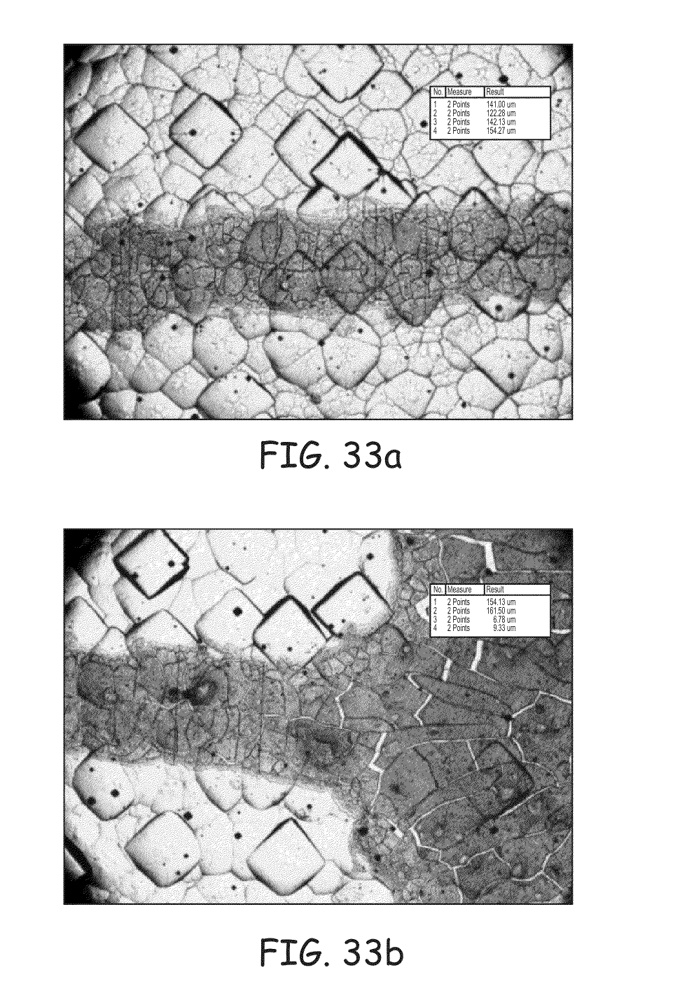

To demonstrate printing performance, the ink was used to manually screen print patterns on a silicon wafer substrate using a 150 μm screen printer line opening. After screen printing, the substrate was baked at 200° C. for 5 min. to cure the ink. FIGS. 33a and 33b are top-view optical microscopy images of portions of the substrate surface showing the cured lines printed with the inks. As shown in the figures, the lines had a width of about 150 nm to about 160 nm. The figures also reveal some cracks in the printed lines. However, the cracks can be prevented by optimizing baking conditions, optimizing the SiO₂ particle concentration, and/or by adding other additives. It is further noted that the printability study of Si/SiO₂ nanoparticle mixing system is still ongoing.

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A paste comprising a solvent and elemental silicon/germanium nanoparticles having an average primary particle diameter of no more than about 75 nm and a concentration of nanoparticles from about 1 weight percent to about 20 weight percent silicon/germanium nanoparticles, wherein the paste has a viscosity at a shear rate of about 2 s⁻¹ from about 2 Pa·s to about 450 Pa·s, a viscosity at a shear rate of about 1000 s⁻¹ of no more than about 1 Pa·s, and a ratio of the viscosity at a shear rate of 2 s⁻¹ to the viscosity at a shear rate of 1000 s⁻¹ of at least about 20.

2. The paste of claim 1 further comprising a cellulose polymer.

3. The paste of claim 1 further comprising from about 0.5 weight percent to about 15 weight percent of a hydrophilic polymer and wherein the paste has from about 1.5 weight percent to about 18 weight percent silicon/germanium nanoparticles.

4. The paste of claim 1 wherein the paste comprises from about 0 weight percent to about 10 weight percent of a first solvent having a boiling point of no more than about 165° C., and from about 65 weight percent to about 94.75 weight percent of a second solvent having a boiling point of at least about 170° C.

5. The paste of claim 4 wherein the second solvent comprises N-methylpyrrolidone, ethylene glycol, propylene glycol, glycol ether, terpineol, 2-(2-ethoxyethoxy)ethanol (Carbitol), butyl cellosolve, or combinations thereof.

6. The paste of claim 4 wherein the first solvent comprises isopropyl alcohol, acetone, dimethylformamide, cyclohexanone or combinations thereof.

7. The paste of claim 1 wherein the particles comprise at least 0.5 atomic percent of dopant.

8. The paste of claim 7 wherein the dopant is phosphorous or boron.

9. The paste of claim 1 wherein the paste has an average viscosity of about 5 Pa·s to about 50 Pa·s at a sheer rate of about 2 s⁻¹.

10. The paste of claim 1 wherein the paste has an average post-printing viscosity at a shear of 2 s⁻¹ that is no less than about 70 percent of an average post-printing viscosity at the 20th print cycle, wherein a print cycle is simulated with the application of a shear rate of about 1000 s-1 to the paste for about 60 seconds followed by applying a low shear rate of about 2 s-1 to the paste for 200 seconds, and wherein the pre-cycling and post-cycling viscosity are measured at about 25° C.

11. The paste of claim 10 wherein the paste has an average post-printing viscosity at a shear of 2 s⁻¹ that is no less than about 90 percent of the post-cycling viscosity of the paste and wherein cycling comprises subjecting the paste to 20 print simulation cycles.

12. The paste of claim 10 wherein the high shear rate is applied for about 60 seconds and wherein the low shear rate is applied for about 200 seconds and wherein cycling is performed at about 25° C.

13. The paste of claim 1 further comprising a dopant liquid.

14. The paste of claim 1 having no more than about 500 parts per billion by weight metal contamination.

15. A silicon nanoparticle paste comprising a solvent and elemental silicon/germanium nanoparticles having an average primary particle diameter of no more than about 75 nm and a concentration of nanoparticles from about 1 weight percent to about 20 weight percent silicon/germanium nanoparticles, wherein the paste has a viscosity at a shear rate of about 2 s⁻¹ from about 1 Pa·s to about 450 Pa·s, wherein the paste has an average post-printing viscosity at a shear of 2 s⁻¹ that is no less than about 70 percent of an average post-printing viscosity, wherein a simulated print cycle is simulated with the application of a shear rate of about 1000 s-1 to the paste for about 60 seconds followed by applying a low shear rate of about 2 s-1 to the paste for 200 seconds, wherein simulated printing comprises subjecting the paste to 20 simulated print cycles and then performing the specified viscosity measurements, and wherein the pre-printing and post-printing viscosities are measured at about 25° C.

16. The paste of claim 15 wherein the paste has a post-printing viscosity that is no less than about 90 percent of the pre-printing viscosity of the paste at the 21th simulated print cycle.

17. A silicon/germanium ink comprising a solvent and from about 0.25 to about 10 weight percent elemental silicon/germanium nanoparticles having an average primary particle size of no more than about 75 nanometers with a viscosity from about 5 cP to about 75 cP, wherein the solvent comprises at least about 95 weight percent alcohol.

18. The silicon/germanium ink of claim 17 having no more than about 500 parts per billion by weight metal contamination.

19. The silicon/germanium ink of claim 17 wherein the alcohol is isopropyl alcohol.

20. The silicon/germanium ink of claim 17 wherein the elemental silicon/germanium nanoparticles have an average primary particle size of no more than about 50 nm.

21. The silicon/germanium ink of claim 17 wherein the elemental silicon/germanium nanoparticles comprise at least about 0.5 atomic percent dopant.

22. A silicon/germanium ink comprising a solvent, from about 0.25 to about 20 weight percent elemental silicon/germanium nanoparticles having an average primary particle size of no more than about 100 nanometers and at least about 1 weight percent silica etching composition.

23. The silicon/germanium ink of claim 22 wherein the silica etching agent comprises HF, NH₄HF₂, NH₄F, or combinations thereof.

24. The silicon/germanium ink of claim 22 wherein the solvent comprises an alcohol.

25. The silicon/germanium ink of claim 22 wherein the elemental silicon/germanium nanoparticles comprise at least about 0.5 atomic percent dopant.

26. A method for applying a silicon ink deposit to a silicon substrate having a silica (silicon oxide) overcoat, the method comprising:
depositing an ink comprising silicon nanoparticles and a silica etchant to form ink deposits over at least a portion of the silica overcoat to etch through the silica overcoat; and
drying the ink deposits to remove solvent and silica etchant and to form a silicon nanoparticle deposit in contact with the silicon substrate.

27. The method of claim 26 wherein the depositing of the ink comprises screen printing.

28. The method of claim 26 wherein the depositing of the ink comprises inkjet printing.

29. The method of claim 26 wherein the depositing of the ink comprises spin coating.

30. The method of claim 26 wherein the drying of the ink comprises heating to a temperature from 50° C. to about 300° C.

31. The method of claim 26 further comprising heating the dried silicon nanoparticle deposit to a temperature from about 700° C. to about 1200° C. to fuse the silicon nanoparticles.

32. The method of claim 26 wherein the silicon nanoparticles are doped and further comprising heating the dried silicon nanoparticle deposit from about 700° C. to about 1200° C. to diffuse dopant into the silicon substrate.

33. An ink comprising a solvent, from about 0.25 to about 20 weight percent elemental silicon/germanium nanoparticles having an average primary particle size of no more than about 100 nanometers and from about 0.25 to about 15 weight percent silica/germania nanoparticles having an average primary particle size of no more than about 100 nanometers.

34. The ink of claim 33 wherein the solvent comprises an alcohol.

35. The ink of claim 33 wherein the silicon/germanium nanoparticles comprise at least about 0.1 atomic percent dopant.

36. The ink of claim 33 wherein the weight ratio of silica/germania nanoparticles to silicon/germanium nanoparticles is from about 0.01 to about 1.

37. A method for the method for producing silicon/germanium nanoparticle inks, the method comprising:
centrifuging an initial well mixed dispersion comprising silicon/germanium nanoparticles in a solvent, to separate a supernatant silicon/germanium nanoparticle dispersion from residue; and
further centrifuging the supernatant solution comprising the silicon/germanium nanoparticle dispersion to separate a multiply centrifuged supernatant as a stable silicon/germanium nanoparticle ink.

38. The method of claim 37 wherein the initial well mixed dispersion is formed using sonication.

39. The method of claim 37 further comprising sonicating the multiply centrifuged supernatant for about 5 minutes to about 3.5 hours.

40. The method of claim 37 wherein each centrifugation step is performed from about 3000 rpm to about 15000 rpm for a time from about 5 minutes to about 2 hours.

41. The method of claim 37 wherein the solvent comprises an alcohol.

42. The method of claim 37 wherein the silicon/germanium nanoparticles comprise at least about 0.5 atomic percent dopant.
